(19) United States
(12) Patent Application Publication
(10) Pub. No.: US 2025/0112600 A1
(43) Pub. Date: Apr. 3, 2025

(54) POWER-ON AND SHUT-DOWN POP REDUCTION IN AUDIO SYSTEMS

(71) Applicant: Texas Instruments Incorporated, Dallas, TX (US)

(72) Inventors: Pourya Assem, Dallas, TX (US); Yogesh Ramadass, Santa Clara, CA (US); Kevin Scoones, San Clara, CA (US); Tim Merkin, Dallas, TX (US); Zejian Wang, Shanghai (CN); Jianquan Liao, Shanghai (CN); Yinglai Xia, Dallas, TX (US)

(21) Appl. No.: 18/476,825

(22) Filed: Sep. 28, 2023

(51) Int. Cl. H03F 3/217; H03F 1/32; H03F 3/38

(52) U.S. Cl. CPC H03F 3/217; H03F 1/3205; H03F 3/38; H03F 2200/03; H03F 2200/351

(57) ABSTRACT

An apparatus includes a first power stage circuit having a first output and a power terminal, and a second power stage circuit having a second output and the power terminal. The apparatus further includes a control circuit having a control input, a first control output, and a second control output. In an example, the control input is coupled to the power terminal, the first control output is coupled to the first output, and the second control output is coupled to the second output. In an example, the control circuit is configured to, responsive to a first voltage at the power terminal being below a threshold voltage, set the first and second outputs to a second voltage.

### CROSS-REFERENCE TO RELATED APPLICATIONS

The present application is related to U.S. application Ser. No. 17/402,264, entitled “Methods and Apparatus to Generated a Modulation Protocol to Output Audio,” filed on Aug. 13, 2021, and U.S. application Ser. No. 17/491,133, entitled “Switching amplifier having linear transition totem pole modulation,” filed on Sep. 30, 2021, which are hereby incorporated by reference in their entireties.

### BACKGROUND

Various audio systems may include an audio amplifier and a speaker. The audio amplifier can receive audio signals representing sound from an audio source, amplify and/or process the audio signals, and provide the amplified/processed audio signals at two electrical terminals of the speaker based on the amplified/converted electrical signals. The amplified/processed electrical signals can set a voltage difference across the two electrical terminals of the speaker, and the speaker can generate the sound based on the voltage difference. In some cases, the audio amplifier may transmit transient signals not originating from the audio source to the speaker. Such transient signals may occur, for instance, when the audio amplifier is powered-up (e.g., from a cold start or after a system reset). Such transient signals can be in the audible frequency band. The transient signals can introduce transient voltage differences between the two electrical terminals of the speaker, which may produce an audible pop sound in response to the transient signals. Such pop sound is undesirable.

### SUMMARY

In an example, an apparatus includes a first power stage circuit having a first output and a first power terminal, and a second power stage circuit having a second output and a second power terminal. The apparatus further includes a control circuit having a control input, a first control output, and a second control output, the control input coupled to the power terminal, the first control output coupled to the first output, and the second control output coupled to the second output, the control circuit configured to, responsive to a first voltage at the first and second power terminals being below a threshold voltage, set the first output to a second voltage and the second output to a third voltage.

In another example, an apparatus comprises a first power stage circuit having a first output and a power terminal, and a second power stage circuit having a second output and the power terminal. The apparatus further comprises a capacitor coupled between the first output and a ground terminal, a speaker having a first speaker terminal and a second speaker terminal, the first speaker terminal coupled to the first output, and an inductor coupled between the second output and the second speaker terminal. The apparatus further comprises a control circuit having a control input, a first control output, and a second control output, the control input coupled to the power terminal, the first control output coupled to the first output, and the second control output coupled to the second output or the second speaker terminal, the controller configured to, responsive to a first voltage at the power terminal being below a threshold voltage, set the first and second outputs to a second voltage.

In yet another example, a method comprises receiving a first voltage that ramps up at respective power terminals of a first power stage circuit and a second power stage circuit, in which the first power stage circuit has a first output and the second power stage circuit has a second output; determining whether the first voltage is below a threshold; and responsive to the first voltage being below the threshold, setting the first and second outputs to a second voltage.

In a further example, a method comprises receiving a first voltage that ramps up at a first power terminal of a power stage circuit coupled to a speaker and at a second power terminal of a power supply circuit; responsive to the first voltage reaching a first threshold voltage, enabling a first voltage regulator of the power supply circuit to provide a second voltage at a driver power terminal of a driver circuit of the power stage circuit; and after enabling of the first voltage regulator, enabling a second voltage regulator of the power supply circuit to increase the second voltage by no more than a particular percentage of the second voltage or at no more than a particular slew rate, in which the percentage or slew rate is based on a pop noise level limit at the speaker.

### BRIEF DESCRIPTION OF THE DRAWINGS

FIGS. 1A and 1B are schematics illustrating examples of an audio system.

FIG. 1C includes graphs illustrating example operations of the audio system of FIGS. 1A and 1B.

FIGS. 2A, 2C, 2D 2E, 2F, and 2G are schematics illustrating additional examples of the audio system of FIGS. 1A and 1B.

FIG. 2B includes graphs illustrating example operations of the example systems of FIGS. 2A and 2C-2G.

FIG. 3 is a schematic illustrating an example control signal generation circuit of FIGS. 2A-2G.

FIG. 4 is a schematic illustrating additional examples of the audio system of FIGS. 1A and 1B.

FIG. 5 is a schematic illustrating an example of a power supply control circuit and a power supply circuit of FIG. 4.

FIG. 6 includes graphs illustrating example operations of the power supply control circuit and the power supply circuit of FIG. 4.

FIG. 7 includes graphs illustrating example operations of the audio system of FIGS. 2A-2G and FIGS. 4-6.

FIG. 8 is a schematic illustrating another example of the power supply control circuit and the power supply circuit of the system of FIG. 4.

FIG. 9 includes graphs illustrating example operations of the power supply control circuit and the power supply circuit of FIG. 8.

FIG. 10 is a schematic illustrating yet another example of the power supply circuit of the system of FIG. 4.

FIG. 11 includes graphs illustrating example operations of the power supply circuit of FIG. 10.

FIG. 12 is an example flowchart representative of a method of operating a speaker.

FIG. 13 is another example flowchart representative of a method of operating a speaker.

### DETAILED DESCRIPTION

Techniques are described herein to eliminate or otherwise reduce the pop sound that sometimes occurs in in audio systems during start-up, whether in the context of a cold-start or a reset. In an example, an apparatus includes a first power stage circuit having a first output and coupled to a power terminal, and a second power stage circuit having a second output and coupled to the power terminal. The apparatus further includes a control circuit having a control input, a first control output, and a second control output. In some such examples, the control input is coupled to the power terminal, the first control output is coupled to the first output, and the second control output is coupled to the second output, and the control circuit is configured to, responsive to a first voltage at the power terminal being below a threshold voltage, set the first and second outputs to a second voltage. In some such cases, the techniques may be implemented with a number of assist transistors coupled at certain nodes of the system. The apparatus may be, for example, part of an audio amplifier system, such as those included in desktop computers, laptop computers, mobile computers (e.g., smartphones), game consoles, or any other electronic device or system that includes speakers driven by an audio amplifier.

In some examples, switching amplifiers are utilized to output audio in various electronics including mobile phones, televisions, hearing aids, home theater systems, vehicle audio systems, instrument amplification, radio frequency amplifiers subwoofers, etc. A switching amplifier includes a power stage that generates a signal having a binary magnitude by selectively connecting the power stage output to one of two supply rails (e.g., a voltage supply and ground, a supply voltage, and a negative voltage supply, etc.). In some examples, the switching amplifier may operate as a class D amplifier. The switching amplifier may be driven by a modulating circuit that receives a sinusoidal audio signal and generates pulse width modulated signals, pulse density signals, and/or any other type of modulated control signals to control the power stage to also generate a modulated signal. The modulated signal provided by the power stage can have a timing property, such as duty cycle, pulse width, etc., modulated/varied to reflect an instantaneous magnitude of the audio signal. The modulated signal generated by the power stage can be filtered (e.g., by a low pass filter) to generate an amplified version of the sinusoidal audio signal, and the amplified sinusoidal audio signal can be fed to a speaker. The low pass filter may include an LC filter including a series inductor coupled between the output of the switching amplifier and the speaker, and a shunt inductor coupled between the speaker and the ground. In some examples, an audio amplifier can include two switching amplifiers as two power stages to provide two modulated signals having opposite polarities at two terminals of the speaker, and an LC filter coupled between each power stage output and a respective terminal of the speaker. The switching amplifier can provide improved power efficiency in driving the speaker, but having two LC filters (especially the inductor) can substantially increase the footprint of the audio system.

In some examples, an audio system can also include a non-switching amplifier. The non-switching amplifier may include another power stage driven by a control circuit including a linear amplifier. The control circuit can receive a sinusoidal audio signal, and provide control signals having magnitudes that varies (e.g., linearly or closed to be linearly) according to an instantaneous magnitude of the audio signal to the non-switching amplifier. Responsive to the control signals, the non-switching amplifier can also generate a signal having a magnitude that varies (e.g., linearly or closed to be linearly) with the audio signal. In some examples, the non-switching amplifier may operate as a class A amplifier, a class AB amplifier, etc. The output of the non-switching amplifier can also be filtered (e.g., by another low pass filter) to remove non-linearities. But because the signal output by the non-switching amplifier has a relatively high linearity (at least compared with the modulated signal provided by a switching amplifier), the low pass filter can have fewer components. For example, instead of an LC filter, an audio system can include a capacitor at the non-switching amplifier output to perform the filtering. In some examples, an audio system can include two non-switching amplifiers as two power stages to provide two linear signals having opposite polarities at two terminals of the speaker, and a capacitor coupled to each power stage output (and a respective terminal of the speaker) to perform the filtering. The lack of inductor can reduce the footprint of the filter and the audio system, but the power efficiency of non-switching amplifiers may be significantly worse than switching amplifiers.

In some examples, an audio system may also include a switching amplifier to drive a first terminal of the speaker, and a non-switching amplifier to drive a second terminal of the speaker. The audio system may include an LC filter coupled between the switching amplifier output and the first terminal, and a capacitor filter coupled to the non-switching amplifier output and the second terminal. With such arrangements, the total number of inductors included in the low pass filters can be halved compared with the case where the audio system includes two switching amplifiers. The power efficiency can also be improved compared with the case where the audio system includes two non-switching amplifiers.

In all these examples of audio systems, there can exist asymmetries in the power stages that drive the speaker. The asymmetries can be due to random mismatch between two amplifiers of the same type (e.g., between two switching or non-switching amplifiers), or can be due to a systematic mismatch (e.g., between a switching amplifier and a non-switching amplifier). Due to the asymmetries, the power stages may introduce a time varying/transient voltage difference across the speaker terminals during the startup or reset of the audio system when the supply voltage to the power stages ramps up, and the audio signals have not yet been provided to the amplifiers. If the time varying voltage difference has a frequency within the human audio frequency band, the speaker may generate an audible pop sound, which is undesirable. Examples disclosed herein provides techniques for avoiding such pop noise during the start-up or reset process.

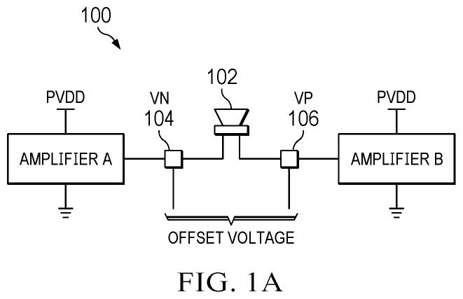

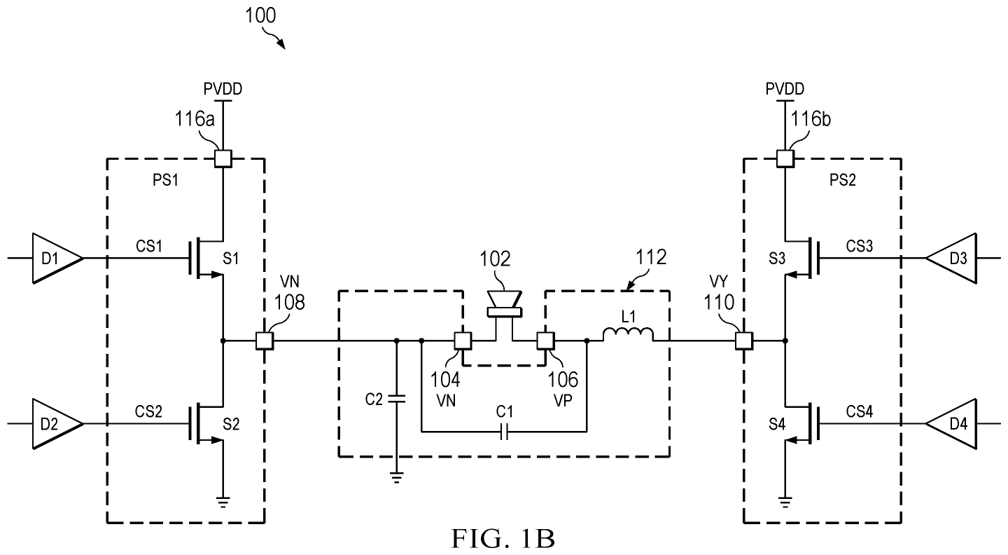

FIG. 1A illustrates an example audio system 100. As shown, system 100 includes a first amplifier (labelled amplifier A) and a second amplifier (labelled amplifier B) driving speaker 102. Amplifier A can be coupled to terminal 104 of speaker 102, and amplifier B can be coupled to terminal 106 of speaker 102. Amplifiers A and B can have the same type (e.g., both being switching amplifiers or non-switching amplifiers), or can have different types and/or have different control schemes (e.g., one being switching amplifier and the other being non-switching amplifier). Because of asymmetries (e.g., random device mismatches or systematic mismatches) between amplifiers A and B, the amplifiers can introduce a time-varying/transient voltage difference between terminals 104 and 106 during a start-up or initialization of the system 100 (e.g., when a supply voltage PVDD is ramping up), which can result in speaker 102 outputting a pop sound. Later, as terminals 104 and 106 become fully charged, a DC voltage offset can develop across capacitor C1 (see FIG. 1B) and between terminals 104 and 106, and the pop sound may end.

Specifically, during a start-up or resetting of the system 100, a supply voltage PVDD of amplifiers A and B may ramp up (e.g., as part of a power sequencing operation), while audio signals are not provided to amplifiers A and B. During this time, the voltages VN and VP may track each other so that the voltage difference can be at zero, or at a DC value, or varies with time but has a very low value (e.g., <10 mV), to avoid (or reduce the possibility of) of the speaker producing audible pop noises. But due to the aforementioned asymmetricities, when the supply voltage PVDD is ramping up (e.g., during a start-up or a reset process), amplifiers A and B may generate a transient voltage difference, which can lead to a transient difference between the voltages VN and VP, resulting in a pop sound produced by the speaker 102. The intensity of the pop sound may be based on an amount of difference between the voltages VP and VN, and may be audible if this difference is relatively large, e.g., larger than 10 mV, 20 mV, or 50 mV, and may be based on volume settings of the speaker 102.

FIG. 1B illustrates examples of internal components of system 100 of FIG. 1A. The system 100 of FIG. 1B includes a first power stage PS1 having a first output terminal 108, and a second power stage PS2 having a second output terminal 110. First power stage PS1 can represent (or can be part of) amplifier A of FIG. 1A, and second power stage PS2 can represent (or can be part of) amplifier B of FIG. 1B. The first output terminal 108 and the second output terminal 110 are coupled to a LC filter circuit 112. Two speaker terminals 104 and 106 (also described with respect to FIG. 1A) of the LC filter circuit 112 are coupled to the speaker 102.

The power stage PS1 comprises a first transistor S1 and a second transistor S2 coupled in series between a power terminal 116a (e.g., receiving a power supply PVDD) and a ground terminal. For example, a first current terminal of the transistor S1 is coupled to the power terminal 116a, and a second current terminal of the transistor S1 is coupled to the output terminal 108. A first current terminal of the transistor S2 is coupled to the output terminal 108, and a second current terminal of the transistor S2 is coupled to the ground terminal.

The transistor S1 further includes a control terminal coupled to a first power stage input that receives a control signal CS1 from a driver D1, and the transistor S2 includes a control terminal coupled to a second power stage input that receives a control signal CS2 from another driver D2. The transistors S1 and S2 can set the voltage VN at output terminal 108 of the power stage PS1 responsive to control signals CS1 and CS2. In FIG. 1B, power stage PS1 can be controlled as a non-switching amplifier (e.g., class AB, class A, etc.), so that CS1 and CS2 can each have a magnitude that varies (e.g., linearly or closed to be linearly) according to an instantaneous magnitude of an audio signal. CS1 and CS2 can have opposite polarities. For example, during a first half cycle of an audio signal, the transistor S1 is on or enabled, the transistor S2 is off or disabled, the transistor S1 can vary a magnitude of the voltage VN based on a magnitude of CS1, which reflects an instantaneous magnitude of the audio signal during the first half cycle. Also, during a second half cycle of the audio signal, the transistor S1 is off or disabled, the transistor S2 is on or enabled, and the transistor S2 can vary a magnitude of the voltage VN based on a magnitude of CS2, which also reflects an instantaneous magnitude of the audio signal during the second half cycle, and the voltage VN can have opposite polarities between the first and second half cycles. In a case where the audio signal is a sinusoidal signal, the voltage VN can be (or close to be) an amplified version of the sinusoidal signal.

In some examples, power stage PS1 can also be controlled as a switching amplifier (e.g., class D), where control signals CS1 and CS2 are pulse width modulated signals, pulse density signals, and/or any other type of modulated control signals having binary magnitudes. Depending on the polarity of the audio signal, one of transistors S1 or S2 can be turned on to connect one of power terminal 116a or ground terminal to output terminal 110. Responsive to CS1 and CS2, power stages PS2 can also generate a modulated signal as VN. The modulated signal provided by the power stage can have a timing property, such as duty cycle, pulse width, etc., modulated/varied to reflect an instantaneous magnitude of the audio signal. CS1 and CS2 can have opposite polarities. For example, during a first half cycle of an audio signal, the transistor S1 is on or enabled, the transistor S2 is off or disabled, the transistor S1 can provide VN as a modulated signal at output terminal 108 responsive to CS1. Also, during a second half cycle of an audio signal, the transistor S2 is on or enabled, the transistor S1 is off or disabled, the transistor S2 can provide VN as a modulated signal at output terminal 108 responsive to CS2.

Also, the power stage PS2 comprises a third transistor S3 and a fourth transistor S4 coupled in series between a power terminal 116b(e.g., receiving a power supply PVDD) and a ground terminal. In an example, the power terminals 116a and 116b may be a same power terminal shared by both the power stages PS1 and PS2, whereas in another example the power terminals 116a and 116b can be coupled to different voltage sources.

As illustrated, a first current terminal of the transistor S3 is coupled to the power terminal 116b, and a second current terminal of the transistor S3 is coupled to the output terminal 110 having a voltage of VY. A first current terminal of the transistor S4 is coupled to the output terminal 110, and a second current terminal of the transistor S4 is coupled to the ground terminal.

The transistor S3 further includes a control terminal coupled to a third power stage input that receives a control signal CS3 from a driver D3, and the transistor S4 further includes a control terminal coupled to a fourth power stage input that receives a control signal CS4 from another driver D4. The transistors S3 and S4 can set the voltage VY at output terminal 110 of the power stage PS2 responsive to control signals CS3 and CS4. In FIG. 1B, power stage PS2 can be controlled as a switching amplifier (e.g., class D), where control signals CS3 and CS4 are pulse width modulated signals, pulse density signals, and/or any other type of modulated control signals having binary magnitudes. Depending on the polarity of the audio signal, one of transistors S3 or S4 can be turned on to connect one of power terminal 16b or ground terminal to output terminal 110. Responsive to CS3 and CS4, power stages PS2 can also generate a modulated signal. The modulated signal provided by the power stage can have a timing property, such as duty cycle, pulse width, etc., modulated/varied to reflect an instantaneous magnitude of the audio signal. CS3 and CS4 can have opposite polarities. For example, during a first half cycle of an audio signal, the transistor S3 is on or enabled, the transistor S4 is off or disabled, the transistor S3 can provide VY as a modulated signal at output terminal 110 responsive to CS3. Also, during a second half cycle of an audio signal, the transistor S4 is on or enabled, the transistor S3 is off or disabled, the transistor S4 can provide VY as a modulated signal at output terminal 110 responsive to CS4. In some examples, power stage PS2 can also be controlled as a non-switching amplifier. In such examples, CS3 and CS4 can each have a magnitude that varies (e.g., linearly or closed to be linearly) according to an instantaneous magnitude of an audio signal.

In FIG. 1B, the transistors S1, S2, S3, and S4 are illustrated as n-channel metal oxide semiconductor (NMOS) field effect transistors (FETs). In other examples, the transistors S1, S2, S3, and S4 can be other types of transistors, such as p-channel MOSFET (PMOS), NPN or PNP bipolar junction transistor (BJT), etc.

The LC filter circuit 112 includes an inductor L1 coupled between the output terminal 110 and the speaker terminal 106, a capacitor C1 coupled between the speaker terminals 104 and 106, and another capacitor C2 coupled between the speaker terminal 104 and the ground terminal. The inductor L1 and capacitor C1 filter the modulated signal VY output at the output terminal 110 into a sinusoidal signal at the speaker terminal 106 that is output to the speaker 102 to output corresponding audio. Capacitor C2 can also filter signal VY to further suppress non-linearities in the signal VY. In a case where power stage PS2 is controlled as a switching amplifier, LC filter circuit 112 also include another inductor (not shown in FIG. 1B) coupled between the output terminal 108 and the speaker terminal 104. In FIG. 1B, output terminal 110 can be a capacitor terminal coupled to the capacitor C2, and output terminal 108 can be an inductor terminal coupled to the inductor L1.

System 100 also includes a control circuit (not shown in FIG. 1B) that generates control signals that respectively drives the driver circuits D1, D2, D3, D4 based on audio signals. Example operations of system 100 are described in related U.S. application Ser. No. 17/402,264, entitled “Methods and Apparatus to Generated a Modulation Protocol to Output Audio,” filed on Aug. 13, 2021, and related U.S. application Ser. No. 17/491,133, entitled “Switching amplifier having linear transition totem pole modulation,” filed on Sep. 30, 2021, which are hereby incorporated by reference in their entireties as described above.

FIG. 1C includes graphs that illustrate example variations of VN and VP voltages when the supply voltage PVDD is ramping up. In FIG. 1C, the supply voltage PVDD ramps up from time t0 to time t2, and has a steady state value after time t2. Time period t0-t2 can depict a start-up (such as a cold start) or a reset operation of the system 100.

Also illustrated in FIG. 1C are voltage VN (illustrated using solid line) and voltage VP (illustrated using dotted line). Both VP and VN increases between times t0 to t1 for reasons described below, decreases between times t1 to t2, and has a substantially steady state value from time t2 onwards. However, between times t0 and t1, the voltages VP and VN are different, resulting in a non-zero transient voltage difference across terminals 104 and 106 of speaker 102. If the transient voltage difference exceeds a certain threshold (e.g., 10 mV) and/or within an audible frequency band, speaker 102 can generate an audible pop sound between times t0-t1 during the start-up or reset operations.

The power stages PS1 and PS2 can introduce the transient voltage difference due to various asymmetries between the power stages. During the ramping of the supply voltage PVDD, charge can be coupled from a power terminal of a power stage to its output (e.g., from 116a to 108, from 116b to 110), which cause the voltages at terminals 108 and 110 to also ramp up. But because of the asymmetries, the voltages at terminals 108 and 110 can ramp up differently, which can lead to the transient voltage difference across the terminals 104 and 106, and the pop noise.

Specifically, each of transistors S1-S4 has parasitic capacitances, represented by dotted-lines capacitor symbols in FIG. 1. When PVDD ramps up from 0 to a steady state value, a rate of increase of voltage with respect to time (e.g., dV/dT) may be high. In an example, the rate of increase of PVDD with respect to time may be in the range of 10 to 100 V/microseconds. Also, at this time, the drivers D1, D2, D3, 04, or the circuits supplying control signals to the drivers D1, D2, D3, D4, may be disabled. The control terminals of the transistors S1-S4 may not be actively driven and may be in a floating state. Via the parasitic capacitance of transistor S1, when PVDD ramps up, charge can move to output terminals 108 and speaker terminal 104, which can lead to a non-zero voltage VN that increases with PVDD. Also, the charge can move to the gate of S1 via the parasitic capacitance and increase the voltage VGS. Between t0-t1, transistor S1 can be turned on and can connect between power terminal 116a and output terminal 108 (and speaker terminal 104). Accordingly, the output terminal 108 experiences a ramp up of the voltage VN between time period t0-t1, as illustrated in FIG. 1C. For similar reasons, when PVDD is ramping up, the output terminal 110 also experiences a ramp up of the voltage VY (and the speaker terminal 106 experiences a ramp up of the voltage VP) between time period t0-t1.

There are various sources of asymmetries between power stages PS1 and PS2 that can lead to different ramping of the voltages VN and VP. One source of asymmetry is filter mismatch. Specifically, output terminal 108 is coupled to ground via capacitor C2, but no corresponding capacitor is coupled to output terminal 110. Also, output terminal 110 is to speaker terminal 106 via inductor L1, but no corresponding inductor is coupled between output terminal 118 and speaker terminal 104. Accordingly, capacitor C2 can provide a low resistance to ground to attenuate (or ground) the ramping voltage VN, while the voltage VP is not similarly grounded/attenuated. The voltage VP also depends on the relative impedance of inductor L1 and capacitors C1 and C2, while the voltage VN has no such dependence on L1. All these can lead to different ramping of the voltages VN and VP, resulting in a transient difference between VN and VP.

Further, power stages PS1 and PS2 may be of different types (e.g., switching amplifier for PS1, non-switching amplifier for PS2), where transistors S1 and S3 have different sizes, and transistors S2 and S4 have different sizes. Even if power stages PS1 and PS2 are of the same type, there may still be mismatches in the transistor sizes between S1 and S3 and between S2 and S4. The mismatches in the transistor sizes can also lead to mismatches in the parasitic capacitances and different amounts of charge that flow to output terminals 108 and 110, which can further increase the transient difference between VN and VY.

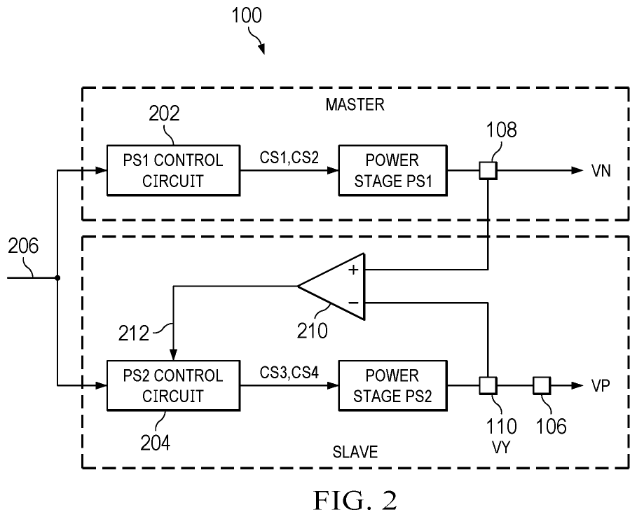

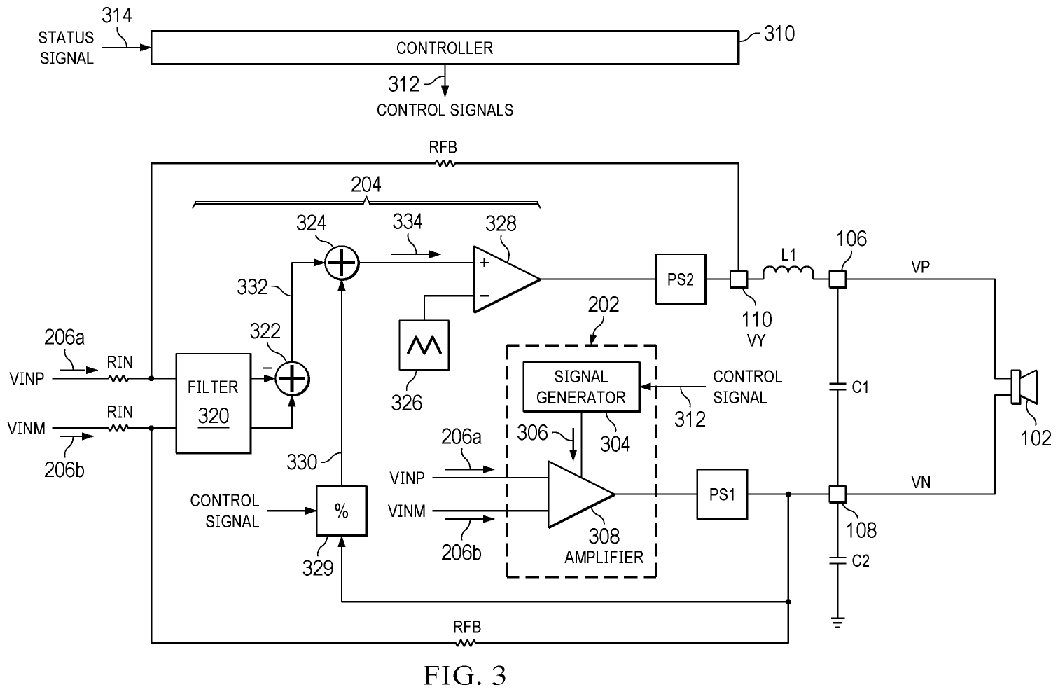

FIG. 2A illustrates an example of system 100 that includes a control circuit 203 configured to eliminate or reduce pop noise. The control circuit operates to configure the system 100 to set the voltages VP and VN at the speaker terminals 104 and 106 of the system 100 to a same DC voltage, or to otherwise reduce the magnitude of the transient voltage difference between those two terminals.

Referring to FIG. 2A control circuit 203 has control outputs 209, 211, 215, and 217. In an example, instead of, or in addition to the control output 215, the control circuit 203 may have a control output 213. As illustrated in FIG. 2A, the control output 209 is coupled to a control terminal of the transistor S1, the control output 211 is coupled to the output terminal 108, the control output 213 is coupled to the speaker terminal 106, the control output 215 is coupled to the output terminal 110, and the control output 217 is coupled to a control terminal of the transistor S3.

In an example and as will be described below, when the voltage PVDD is ramping and is below a threshold voltage, the control outputs 209 and 217 may connect the control terminals of the transistors S1 and S3, respectively, to a ground terminal, or to a state to disable transistors S1 and S3. With transistors S1 and S3 disabled, output terminal 108 can be disconnected from power terminal 116a, and output terminal 110 can be disconnected from power terminal 116b, which can reduce (or eliminate) flow of charge from power terminals 116a and 116b through the current terminals of transistors S1 and S3 to the respective output terminals 108 and 110 during the ramping of the supply voltage PVDD. Such arrangements can reduce the ramping of VP and VN and the resulting transient difference between VP and VN.

Also, the control circuit 203 is configured to, responsive to the supply voltage PVDD at the power terminals 116a and/or 116b being below a threshold voltage, set the terminals 108, 106, and/or 110 at a same voltage, e.g., using the control outputs 211, 213, and/or 215, respectively. Such arrangements can further reduce the difference between VP and VN (and the voltage difference between speaker terminals 104 and 106) due to asymmetric flow of charge from power terminals 116a and 116b through the parasitic capacitances of transistors S1 and S3 to the respective output terminals 108 and 110.

In an example and as will be described below, when the voltage PVDD is ramping and is below a threshold voltage, the control outputs 211 and 213 may connect the terminals 108 and 106, respectively, to a ground terminal. Accordingly, the voltages VN and VP can be substantially the same (at 0 volt), and hence, the above described pop noise from the speaker 102 may be avoided or at least reduced.

In another example and as will also be described below, when the voltage PVDD is ramping and is below a threshold voltage, the control outputs 211 and 215 may also connect the terminals 108 and 110, respectively, to a ground terminal. Accordingly, the voltages VN and VY may be substantially zero, and hence, voltage VN may also be substantially zero. Accordingly, the above described pop noise from the speaker 102 may be avoided or at least reduced.

In yet another example and as will also be described below, when the voltage PVDD is ramping and is below a threshold voltage, the control outputs 211 and 213 may connect the terminals 108 and 106, respectively, to a fixed/DC voltage. Accordingly, the voltages VN and VP may be substantially the same, and hence, any difference between the voltages VN and VP is eliminated or at least reduced. Accordingly, the above described pop noise from the speaker 102 may be avoided or at least reduced.

In yet another example and as will also be described below, when the voltage PVDD is ramping and is below a threshold voltage, the control outputs 211 and 213 may connect the terminals 108 and 106, respectively, to different DC voltages, which can result in a DC voltage offset between the terminals 108 and 106 and eliminate/reduce transient voltage difference between speaker terminals 104 and 106. Accordingly, the above described pop noise from the speaker 102 may be avoided or at least reduced.

FIG. 28 illustrates a timing diagram depicting voltages VN and VP at speaker terminals 104 and 106 of the system 100 of FIG. 2A, e.g., when the supply voltage PVDD is ramping up. For example, in FIG. 2B, the supply voltage PVDD ramps up from time t4 to time t5, and has a steady state value after time t5. Thus, time period t4-t5 depicts a start-up (such as a cold start) or reset operation of the system 100. Because of the above described operation of the control circuit 203, the voltages VN and VP are relatively small and substantially track each other (e.g., compared to those of the timing diagram of FIG. 18). This can eliminate or at least reduce the pop noise at the speaker 102 during the ramping of the supply voltage PVDD.

Referring again to FIG. 2A, the control circuit 203 comprises one or more transistors, such as assist transistors AS1, AS2, AS3, and AS4, each of which will be described below. As illustrated in FIG. 2A, the control circuit 203 further comprises a control signal generation circuit 207 that generates a control signal CSS, where the CSS is coupled to a control terminal of each of the assist transistors AS1, AS2, AS3, and AS4.

FIG. 2C illustrates another example of system 100 including control circuit 203. Referring to FIG. 2C, an assist transistor AS1 is coupled to a control terminal of the transistor S1 of the power stage PS1, another assist transistor AS3 is coupled to a control terminal of the transistor S3 of the power stage PS2, another assist transistor AS2 is coupled to an output terminal 108 of the power stage PS1, and another assist transistor AS4 is coupled to an output terminal 110 of the power stage PS2. The control circuit 203 comprises the assist transistors AS1, AS2, AS3, and AS4, along with the control signal generation circuit 207. An outline of the control circuit 203 is not illustrated in FIG. 2C (see FIG. 2A for the outline of the control circuit 203).

In one example, the system 100 includes a die 208 comprising the power stages PS1 and PS2, the assist transistors AS1, AS2, AS3, and AS4, the control signal generation circuit 207, and the drivers D1-D4. As illustrated, in FIG. 2C, the assist transistor AS1 is coupled between the control output 209 (which is coupled to the control terminal of the transistor S1, see FIG. 2A) and the ground terminal. The assist transistor AS3 is coupled between the control output 217 (which is coupled to the control terminal of the transistor S3, see FIG. 2A) and the ground terminal.

The assist transistor AS2 is coupled between the control output 211 (see also FIG. 2A, where the control output 211 is coupled to the output terminal 108) and the ground terminal. The assist transistor AS4 is coupled between the control output 215 (see also FIG. 2A, where the control output 215 is coupled to the output terminal 110) and the ground terminal.

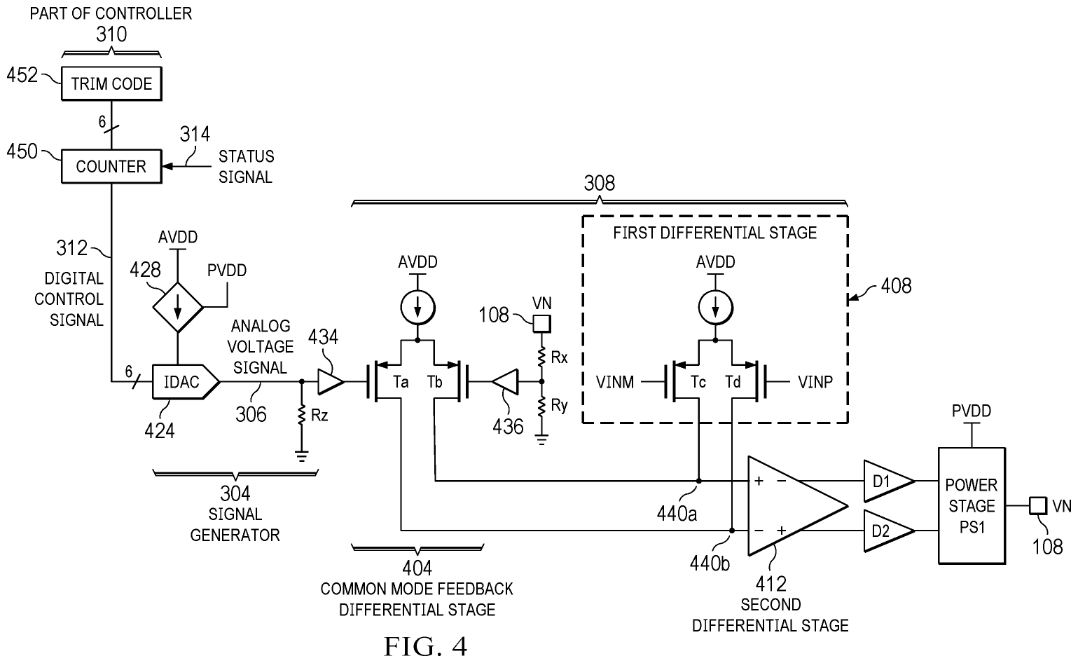

In one example, the control circuit 203 comprises the control signal generation circuit 207 that generates the control signal CSS, where CSS is coupled to a control terminal of each of the assist transistors AS1, AS2, AS3, and AS4. Generation of the control signal CSS is described herein below with respect to FIG. 3. For example, each of the assist transistors AS1, AS2, AS3, and AS4 receives the same control signal CSS.

As illustrated in FIG. 21, the control signal generation circuit 207 generates the control signal CSS, such that the assist transistors AS1-AS4 are enabled or on at least in part during a ramping up of the supply voltage PVDD (generation of the control signal CSS will be described below in further detail). For example, the timing diagram of FIG. 2B illustrates the assist transistor control signal CSS being enabled and the assist transistors AS1-AS4 being on from time t4 to at least time t5, e.g., based on the PVDD being less than a threshold voltage, where time t5 occurs at or subsequent to PVDD reaching a steady state value. In some examples, the assist transistors may continue to be enabled (e.g., for a short duration) after time t5, or throughout the entire duration when PVDD is ramping up (e.g., between t4 and t5).

As described above with respect to FIG. 2A, when the voltage PVDD is ramping and is below the threshold voltage, the assist transistors AS1 and AS3 are enabled, and connect the control terminals of the transistors S1 and S3, respectively, to the ground terminal, or to a state that disables transistors S1 and S3. Accordingly, the transistors S1 and S3 remain off or disabled, and the supply terminals 116a, 116b are disconnected from the output terminals 108 and 110, respectively.

With such arrangements, the ramping of voltages VN and VY, caused by the ramping of PVDD and the flow of charge through transistors S1 and S3, can be reduced. Also, as described above, the assist transistors AS2 and AS4 can connect the output terminals 108 and 110, respectively, to a ground terminal, which can ground both voltages VN and VY between time t4 and t5 (see FIG. 2B). Hence, voltage difference between the speaker terminals 104 and 106 is relatively small and can be substantially zero. This results in elimination, or reduction of a pop sound during the ramping of PVDD.

FIG. 2D illustrates another example of system 100 including control circuit 203. Referring to FIG. 2D, an assist transistor AS1 is coupled to a control terminal of the transistor S1 of the power stage PS1, another assist transistor AS3 is coupled to a control terminal of the transistor S3 of the power stage PS2, another assist transistor AS2 is coupled to an output terminal 108 of the power stage PS1, and another assist transistor AS4 is coupled to a speaker terminal 106. Thus, the connections and/or operations of the assist transistors AS1, AS2, and AS3 in FIGS. 2C and 2D are the same. In FIG. 2D the assist transistor AS4 is coupled to the speaker terminal 106. In FIG. 2D the speaker terminal 106 is on the die 208. In operation, in FIG. 2D, the assist transistor AS4 grounds the speaker terminal 106 (e.g., instead of the output terminal 110), e.g., when the PVDD is ramping up during the time t4-t5 of FIG. 2B. Operations of the assist transistors AS1-AS4 in FIG. 2D will be apparent, based on the description with respect to FIG. 2C.

In FIG. 2D (and also in FIGS. 2E and 2F), an output terminal 212 is on the die 208. In an example, the inductor L1 is part of the power stage PS2, where the power stage P2 includes transistors S3, S4, and inductor L1. The speaker terminal 106 may be coupled to an output terminal 212 of the power stage PS2, in addition to output terminal 110. In some examples, inductor L1 is external to the power stage PS2. In such examples, the power stage PS2 has an output terminal 110, die 208 has an output terminal 212, and inductor L1 is coupled between output terminals 212 and 110.

FIG. 2E illustrates yet another example of system 100 including control circuit 203. Referring to FIG. 2E, output terminal 108 of the power stage PS1 and output terminal 212 of the power stage PS2 (or die 208) can be selectively shorted together using an assist transistor AS2, e.g., between time t4-t5 when PVDD is below a threshold. Also, the connections and/or operations of the assist transistors AS1 and AS3 in FIGS. 2C and 2E are the same. By shorting output terminals 108 and 212, voltages VN and VP can become substantially the same, resulting in elimination or reduction in the pop noise during startup of the system 100 of FIG. 2E.

FIG. 2F illustrates another example of system 100 including control circuit 203. In FIG. 2F, output terminal 108 of the power stage PS1 and output terminal 212 (of output stage PS2 and/or die 208) are each selectively connected to a voltage source Vs, e.g., between time t4-t5. The connections and/or operations of the assist transistors AS1 and AS3 in FIGS. 2D and 2F are the same. As the output terminals 108 and 212 are each connected to the voltage source VS during this time period, voltages VN and VP are substantially the same (e.g., same as the voltage VS), resulting in elimination or reduction in the pop noise during start-up of the system 100 of FIG. 2F.

FIG. 2G illustrates another example of system 100 including control circuit 203. In FIG. 2G, current terminals of the assist transistors AS1, AS2, AS3, and AS4 are respectively connected to voltages V1, V2, V3, and V4. Each of the voltages V1-V4 may be zero volt (e.g., grounded), or a non-zero DC voltage. The assist transistors AS2 and AS4, when enabled, can connect the output terminal 212 and the output terminal 108 to voltages V2 and V3, respectively, e.g., between time t4-t5. In an example, the voltages V2 and V3 are the same, resulting in a DC offset (and elimination of transient voltage difference) between speaker terminals 104 and 106, thereby resulting in elimination or reduction in the pop noise during start-up of the system 100 of FIG. 2F.

FIG. 3 illustrates examples of internal components of the control signal generation circuit 207. As described with respect to FIGS. 2A-2G, the control signal generation circuit 207 generates the control signal CSS, which is used to control the assist transistors AS1-AS4.

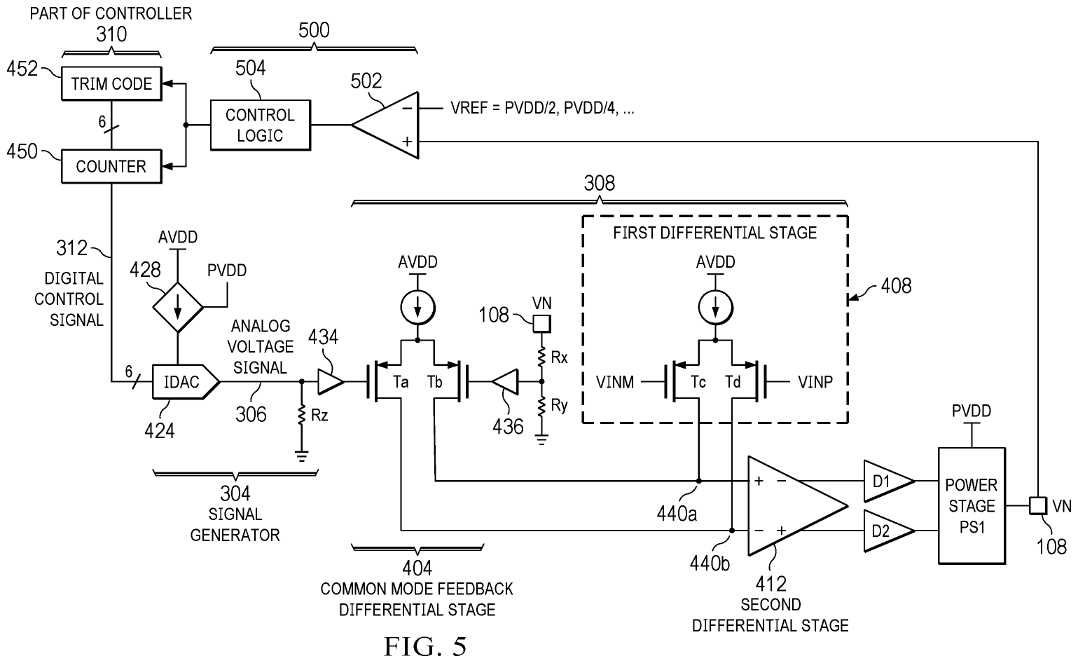

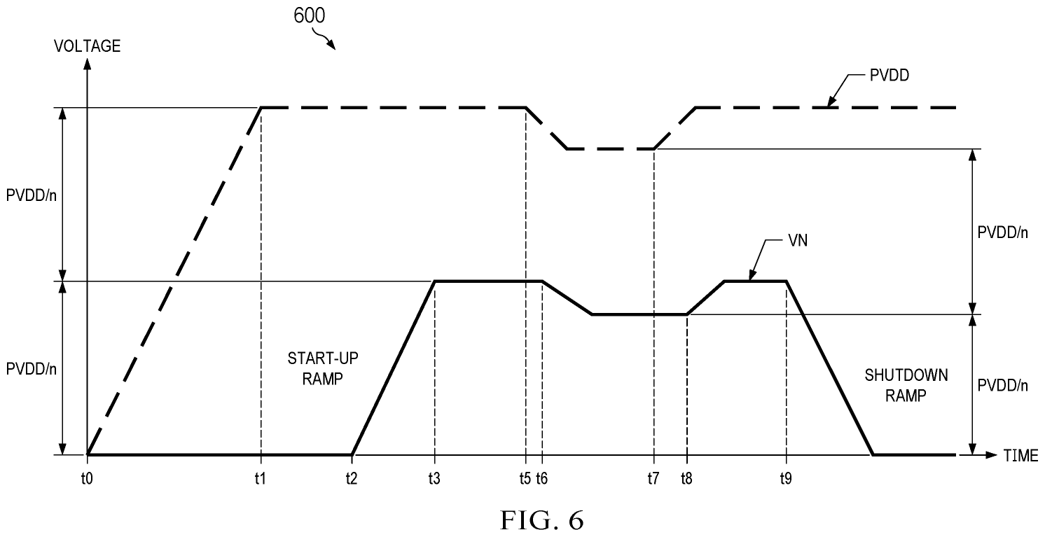

The control signal generation circuit 207 includes a voltage regulator 304 configured to receive the supply voltage PVDD (e.g., from the power supply terminals 16a and/or 116b), and generate a regulated voltage GVDD_f. In an example, the voltage regulator 304 is a relatively fast regulator, e.g., generating the output voltage GVDD_f within a few microseconds of the ramping of PVDD, such that the assist transistors AS1-AS4 can be switched on almost as soon as the voltage PVDD starts ramping up (e.g., see FIG. 2B). In an example, the voltage regulator 304 may be of a relatively small capacity and faster in speed (e.g., compared to voltage regulators described herein below with respect to FIG. 5), e.g., as the voltage regulator 304 may supply GVDD_f voltage and power for operations of relatively small number of components, such as the control signal generation circuit 207 and the assist transistors AS1-AS4. The suffix “_f” is added to GVDD in FIG. 3, to distinguish this GVDD supply from a different GVDD supply described herein below with respect to FIGS. 4 and 5.

The control signal generation circuit 207 further includes an undervoltage lockout circuit 308 configured to receive the supply voltage PVDD, and generate a undervoltage lockout (UV) signal 309. In one example, the undervoltage lockout circuit 308 is biased or powered by GVDD_f.

In an example, the undervoltage lockout circuit 308 has a control input 307 coupled to the power supply terminal 116a and/or 116b, and receives the power supply voltage PVDD. The undervoltage lockout circuit 308 compares the PVDD with a threshold voltage Vth, and generates the UV signal 309 at a first state when the PVDD is lower than a threshold voltage, and generates the UV signal 309 at a second state when the PVDD is higher than the threshold voltage. For example, during a start-up or reset of the system 200, the PVDD ramps from zero to a steady state value, as illustrated in the timing diagram of FIG. 2B. For example, during time period t4-t5, the PVDD is less than the threshold voltage, and the UV 309 is at a first logic state (e.g., logic HIGH) during this time period. Subsequent to time t5, PVDD is higher than the threshold voltage, and hence, the UV 309 is at a second logic state (e.g., logic LOW) during this time period. In an example, the undervoltage lockout circuit 308 acts as a voltage comparator, and can be replaced by a voltage comparator.

As further shown in the example embodiment of FIG. 3, logic circuit 312 receives the UV signal 309, and generates the control signal CSS responsive to the UV signal 309. For instance, responsive to the UV signal 309 indicating the PVDD being below the threshold voltage (e.g., during time period t4 to t5), and in this particular example, further responsive to SC signal 317 indicating no short circuit is detected as described below, the control signal CSS is set at a first logic state (e.g., logic HIGH) to enable assist transistors AS1-AS4, such as shown in FIG. 2B. On the other hand, in response to the UV signal 309 being a logic LOW thereby indicating the PVDD is higher than the threshold voltage (e.g., subsequent to time t5), the control signal CSS is set at a second logic state (e.g., logic LOW) to disable assist transistors AS1-AS4.

As further shown in the example of FIG. 3, the control signal generation circuit 207 may further include a short circuit protection circuit 316. For example, the short circuit protection circuit 316 can be configured to detect any short circuit occurring in the system 100, such as by sensing high current relative to a given reference current, or by sensing a low voltage relative to a given reference voltage. For example, responsive to a short circuit occurring between the power supply terminals 116a or 116b and ground or other node that would cause a detectable high current condition (such as any of the terminals 108, 104, 106, or 110, in some cases), the short circuit protection circuit 316 generates a short circuit (SC) signal 317 at a particular state (e.g., logic LOW) indicative of the short circuit. Responsive to SC signal 317 indicating the short circuit (and/or irrespective of the state of the UV 309), the logic 312 can generate the CSS at the second logic state. In some such examples, logic 312 can be an AND gate and can set CSS to a logic LOW state responsive to signal 317 being a logic LOW signal indicating a short circuit. If no short circuit is detected, then the short circuit protection circuit 316 sets SC signal 317 at another state (e.g., logic HIGH) indicating normal operation, which in turn allows logic 322 to determine CSS based on UV signal 309. For instance, and continuing with the example where logic 312 is an AND gate, logic 312 can set CSS to a logic HIGH state responsive to UV signal 309 also having a logic HIGH state (indicating the PVDD is below the threshold voltage, during start-up process) and signal 317 having a logic HIGH state (indicating no short circuit is detected).

Thus, in case of any short circuit, the assist transistors AS2 and AS4 can be switched off. Such a configuration may be used to prevent damage due to high current caused by a short circuit, such as between the power supply PVDD and the ground terminal through the short circuit and either of the assist transistors AS2 or AS4 (e.g., as the assist transistors AS2 and AS4 are disabled or switched off). Furthermore, switching off the assist transistors AS2 and AS4 during a short circuit may also reduce or eliminate over-voltage stress on the gate terminals of S1 and S3.

In still other examples, circuits 312 and 316 are not included, and UV signal 309 generated by circuit 308 is used to enable or disable the assist transistors AS1-AS4. Other configurations may be used as well, and logic 312 can be tailored to allow for consideration of other sensed conditions (e.g., open circuit condition, floating condition, high-capacitance condition, to name a few examples).

FIG. 4 illustrates a bootstrap circuit 404 for bootstrapping a driver D3 of the power stage PS2 of system 100, where a power supply circuit 414 of the system 100 includes mechanism to avoid a pop sound at the speaker output of the system 100. System 100 of FIG. 4 also includes assist transistors AS1-AS4, which are not illustrated in FIG. 4.

As illustrated in FIG. 4, each of the drivers D1-D4 has a respective driver output coupled to a control terminal of one of transistors S1-S4. For example, driver D1 has a first driver output coupled to a control terminal of the transistor S1 providing a first power stage input. Similarly, driver D2 has a second driver output coupled to a control terminal of the transistor S2 providing a second power stage input. Similarly, driver D3 has a third driver output coupled to a control terminal of the transistor S3 providing a third power stage input. Similarly, driver D4 has a fourth driver output coupled to a control terminal of the transistor S4 providing a fourth power stage input.

In an example, system 100 includes a charge pump 408 to bias the driver D1 of the power stage PS1, whereas the bootstrap circuit 404 can bias the driver D3 of the power stage PS2. In one example, the bootstrap circuit 404 comprises a bootstrap switch SBST coupled between a power supply terminal 407 supplying a regulated power supply GVDD and a bootstrap capacitor CBST. The bootstrap capacitor CBST has a first terminal coupled to the bootstrap switch SBST, and a second terminal coupled to the output terminal 110 of the power stage PS2. The first terminal of the bootstrap capacitor CBST is also coupled to a driver power terminal 409 of the driver D3. In an example, during bootstrapping of the driver D3, energy is stored in the capacitor CBST from the GVDD power supply terminal 407 through the switch SBST. This energy provides biasing power to the driver D3. Another driver power terminal 413 is coupled to the output terminal 110. Thus, the driver power terminals 409 and 413 bias the driver D3.

In the example of FIG. 4, the second power stage PS2 may operate as a switching amplifier and includes the bootstrap circuit 404 to increase the supply voltage of driver D3. This allows D3 to increase the voltage swing of control signal CS3 to fully switch on/off transistor S3. Also, the first power stage PS1 may operate as a non-switching amplifier, and the supply voltage of driver D1 needs not be as high as driver D3. Accordingly, driver D1 can be biased by charge pump 408.

The power for biasing the driver D3, through the bootstrap circuit 404, is supplied by the regulated supply voltage GVDD from the power supply terminal 407. A power supply circuit 414 has a power output 416 that supplies the voltage GVDD at the power supply terminal 407. The power supply circuit 414 has a power input 417 coupled to the power supply terminals 116a, 116b, and hence, the power input 417 to the power supply circuit 414 receives the supply voltage PVDD. In the example of FIG. 4 the power supply circuit 414 is external to the die 208, although in another example the power supply circuit 414 may be at least in part internal to the die 208.

The power supply circuit 414 has a power supply control input 418 coupled to a power supply control output 419 from a power supply control circuit 420 of the control circuit 203. The power supply control input 418 receives a power supply control signal GVDD_En_delayed from the control circuit 203, and based at least in part on the power supply control signal GVDD_En_delayed, generates the regulated voltage GVDD from the power supply PVDD.

The control circuit 203 comprises, in addition to the assist switches AS1-AS4 and the control signal generation circuit 207, the power supply control circuit 420. The power supply control circuit 420 generates the power supply control signal GVDD_En_delayed, and supplies the power supply control signal GVDD_En_delayed to the power supply circuit 414.

In an example, during start-up or reset of the system 100, if the rate of increase of GVDD is too high (e.g., higher than a threshold level), the voltage VY may also rise with GVDD. Specifically, during a start-up or reset of the system 100, the control terminal of the switch SBST can be floating or not yet actively driven. As GVDD increases, charge may flow to the control terminal (e.g., gate) of SBST (e.g., due to parasitic capacitance of the switch SBST), which can increase the gate voltage and turn on SBST. Also, with SBST turns on, the capacitor CBST can transmit the increasing GVDD voltage (through AC coupling) to the output terminal 110 and increase the voltage VY, which also increases the voltage VP at the speaker terminal 106. On the other hand, the voltage VN at the output terminal 108 may not experience the same increase as the voltage VP at least because the first power stage PS1 does not have a bootstrap circuit coupled between GVDD and output terminal 108, and/or due to mismatch between first and second power stages PS2 as explained above. Also, as charge pump 408 biases the driver D1, the output terminal 108 does not receive a voltage that increases at a same high rate as the output terminal 110. Accordingly, the voltage VY (and the voltage VP) may be different from (e.g., higher than) the voltage VN. This transient voltage difference between the voltages VN and VP may cause a pop sound at the speaker 102, as described above. In some examples, as to be described below, the power supply circuit 414 can control the rise of the GVDD voltage to avoid or reduce such a pop sound.

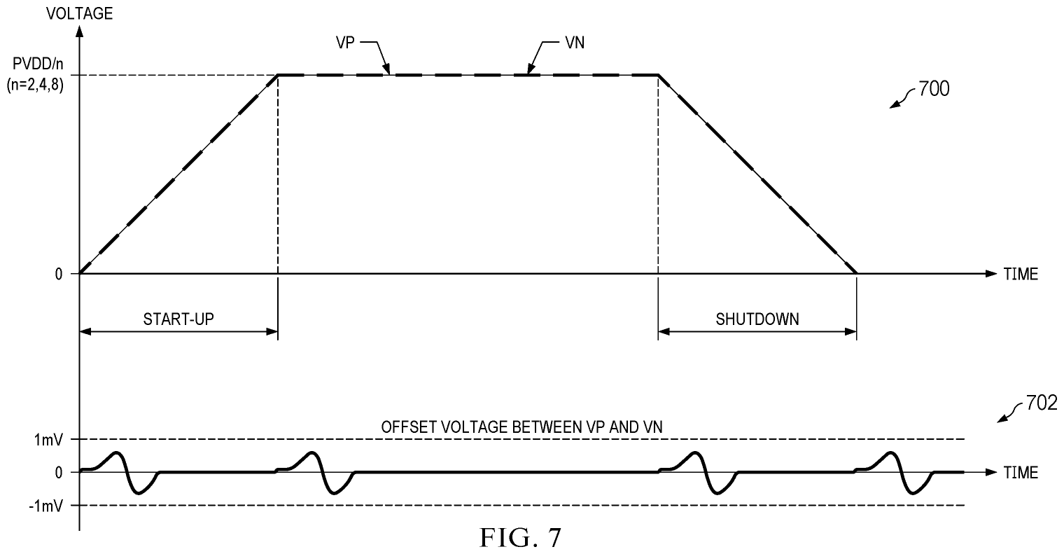

FIG. 5 illustrates an example implementation of the power supply control circuit 420 and the power supply circuit 414 of the system 400 of FIG. 4, and FIG. 6 illustrates a timing diagram 600 depicting an operation of the power supply control circuit 420 and the power supply circuit 414.

Referring to FIG. 5, in one example, the power supply circuit 414 comprises a weak GVDD regulator 504 and a strong GVDD regulator 508 configured to generate the regulated power supply GVDD, from the power supply PVDD. The adjectives “weak” and “strong” are used herein, e.g., to signify that the weak GVDD regulator has a relatively lower power rating (e.g., supplying a lower current) than the strong GVDD regulator.

For example, during a start-up or resetting of the system 400, the weak GVDD regulator 504 initially starts up or resets, and powers one or more components of the system 400 that participates in the start-up or reset process. In an example, the weak GVDD regulator 504 may not have capacity to supply the current to all components of the system that are to receive the GVDD voltage. Accordingly, to augment (or later replace) the power of the weak GVDD regulator 504, the strong GVDD regulator 508 is initiated after some time (described below with respect to the timing diagram of FIG. 6). For example, subsequent to the starting of the strong GVDD regulator 508, only the strong GVDD regulator 508 (or both the strong GVDD regulator 508 and the weak GVDD regulator 504) may supply power to the components consuming GVDD. Accordingly, subsequent to the starting of the strong GVDD regulator 508, the weak GVDD regulator 504 may continue to remain on, or may be turned off.

Referring now to the timing diagram of FIG. 6, illustrated is a GVDD voltage profile at the power supply terminal 407. The straight line portion 604 illustrates GVDD generated by the weak GVDD regulator 504, and the two curved line portions 604 and 608 illustrate two different scenarios, where each scenario depicts contribution from the strong GVDD regulator 508 and the weak GVDD regulator 504.

In the example of FIG. 6, a steady state value of GVDD at terminal 407 is about 5 V, which is a mere example. At time t9, the weak GVDD regulator 504 is started, e.g., based on a ramp up or a steady state value of the power supply PVDD. For example, a weak_en control signal 510 is received by the weak GVDD regulator 504 (e.g., from the power supply control circuit 420), where the weak_en control signal 510 is received responsive to the PVDD ramping up, or reaching at least a threshold value. The weak GVDD regulator 504 starts generating the GVDD from the time t9 using power supply PVDD, based on receiving the weak_en control signal 510. This results in a gradual increase of the GVDD at the power supply terminal 407.

In a first example, the strong GVDD regulator 508 is started at time t10(illustrated using dotted line 608 in FIG. 6); and in a second example, the strong GVDD regulator 508 is started at time t11 (illustrated using solid line 612 in FIG. 6).

If the strong GVDD regulator 508 is started at time t10 (see resultant dashed curve 608), the GVDD at the power supply terminal 407 has a relatively small value at time t10, such as a value of about 2.5 V, as illustrated in FIG. 6. Once the strong GVDD regulator 508 is started at time t10, there is a jump in the GVDD at the power supply terminal 407. For example, the GVDD at the power supply terminal 407 jumps from about 2.5 V to about 5 V during a relatively short period of time. Note that at this time, the control terminal of the switch SBST isn't powered, and this sudden increase in the GVDD turns on the switch SBST due to parasitic capacitances of the switch. Also, due to the high rate of rise of the GVDD (e.g., high dV/dT), the capacitor CBST AC couples the GVDD to the output terminal 110. Accordingly, due to the high rate of rise (e.g., dV/dT) of GVDD from time t10 (e.g., based on switching on the strong GVDD regulator 508 at time t10), capacitor CBST may supply at least a part of the GVDD voltage to the output terminal 110, resulting in an increase in VY, and a resultant increase in the voltage VP at the speaker terminal 106. This may cause a pop noise at the speaker 102.

In contrast, if the strong GVDD regulator 508 is started at time t11 (see solid curve 612), the GVDD at the power supply terminal 407 has a relatively large value at time t11, such as a value of about 4.6 V, as illustrated in FIG. 6. Once the strong GVDD regulator 508 is started at time t11, there is a relatively smaller jump in the GVDD at the power supply terminal 407. For example, the GVDD at the power supply terminal 407 jumps from about 4.6 V to about 5 V. Accordingly, as this jump is small, this jump may not result in the above described problems associated with a start of the strong GDVV regulator at time t10.

Accordingly, by delaying the start of the strong GVDD regulator 508 from time t10 to time t11, the rate of rise of GVDD is reduced. For example, starting at t0 results in GVDD rapidly rising from 2.5 V to 5 V (e.g., a jump of 2.5V); whereas starting at t11 results in GVDD rising from 4.6 V to 5 V (e.g., a jump of only 0.5V). Thus, by delaying the start of the strong GVDD regulator 508 from time t10 to time t1, the pop sound in the speaker 102 due to the jump in the GVDD may be avoided or at least reduced.

Referring again to FIG. 5, the power supply control circuit 420 comprises an undervoltage lockout circuit 424 configured to receive a reference voltage Vref1 and a feedback of the regulated power supply GVDD from the power supply terminal 407. The undervoltage lockout circuit 424 compares the feedback voltage GVDD with the reference voltage Vref1. In response to the feedback voltage GVDD being at least as high as the reference voltage Vref1, the undervoltage lockout circuit 424 enables a power supply control signal GVDD_En. For the example timing diagram of FIG. 6, the reference voltage Vref1 may be about 2.5 V, or any other voltage that is less than 4.6 V.

Note that if the strong GVDD regulator 508 is initiated based on the power supply control signal GVDD_En, then the regulated GVDD may experience a relatively high jump (e.g., high dV/dT), possibly resulting in the above described pop noise. Accordingly, the power supply control signal GVDD_En is delayed by a delay circuit 428, which receives the power supply control signal GVDD_En and generates a delayed power supply control signal GVDD_En_delayed. For example, if power supply control signal GVDD_En is enabled at time t10, then the delayed power supply control signal GVDD_En_delayed is enabled after some pre-configurable delay, such as at time t11 of FIG. 6.

Thus, the delayed power supply control signal GVDD_En_delayed is enabled at time t11, for example. The strong GVDD regulator 508 receives the delayed power supply control signal GVDD_En_delayed, and initiates generation of GVDD, responsive to the delayed power supply control signal GVDD_En_delayed being enabled at time t11. As described with respect to FIG. 6, enabling the strong GVDD regulator 508 at time t1 results in relatively less jump in the GVDD at the power supply terminal 407, and hence, no or reduced chances of the pop noise at the speaker 102.

Thus, in an example, the delay 428 is configured such that the power supply circuit 414, responsive to the delayed power supply control signal GVDD_En_delayed, increases GVDD by a relatively small amount (e.g., from 4.6 V to 5 V in the example of FIG. 6). In various examples, the increase in the GVDD, responsive to the GVDD_En_delayed, may have a particular upper limit, such as 2 V, 1.5 V, 1 V, 0.5 V, etc., and may be implementation specific (such as depending on the system design). In the example of FIG. 6, the increase in the GVDD is 0.4 V).

In various examples, the increase in the GVDD, responsive to the GVDD_En_delayed, may be limited at a particular percentage of the current GVDD value, such as 50%, 40%, 30%, 20%, or 10%, and may be implementation specific (such as depending on the system design). For example, in FIG. 6, the increase in GVDD at time t11 is from 4.6 V to about 5V, or 0.4 V, which is less than 10% of 4.6 V.

In various examples, the increase in the GVDD, responsive to the GVDD_En_delayed, may have slew rate equal to or lower than, for example, 1 V/20 microseconds, 1 V/10 microseconds, 1 V/5 microseconds, 1 V/1 microseconds, etc., and may be implementation specific (such as depending on the system design).

In an example, the increase in the GVDD, responsive to the GVDD_En_delayed, whether expressed as voltage value, or as a percentage, or as a slew rate, may be based on a speaker pop noise limit and/or sensitivity of the system (such as ability of the system to handle the increase). For example, if the speaker 102 can tolerate an increase of 2 V increase or 20% increase in GVDD at time t11 without producing an audible pop sound, then the power supply control circuit 420 may be configured to enable the GVDD_En_delayed at a time such that there is at most 2 V or 20% increase in the GVDD. Of course, there may be a margin of error, and so, the power supply control circuit 420 may be configured to enable the GVDD_En_delayed at a time such that there is at most 1.8 V or 18% increase in the GVDD, for example.

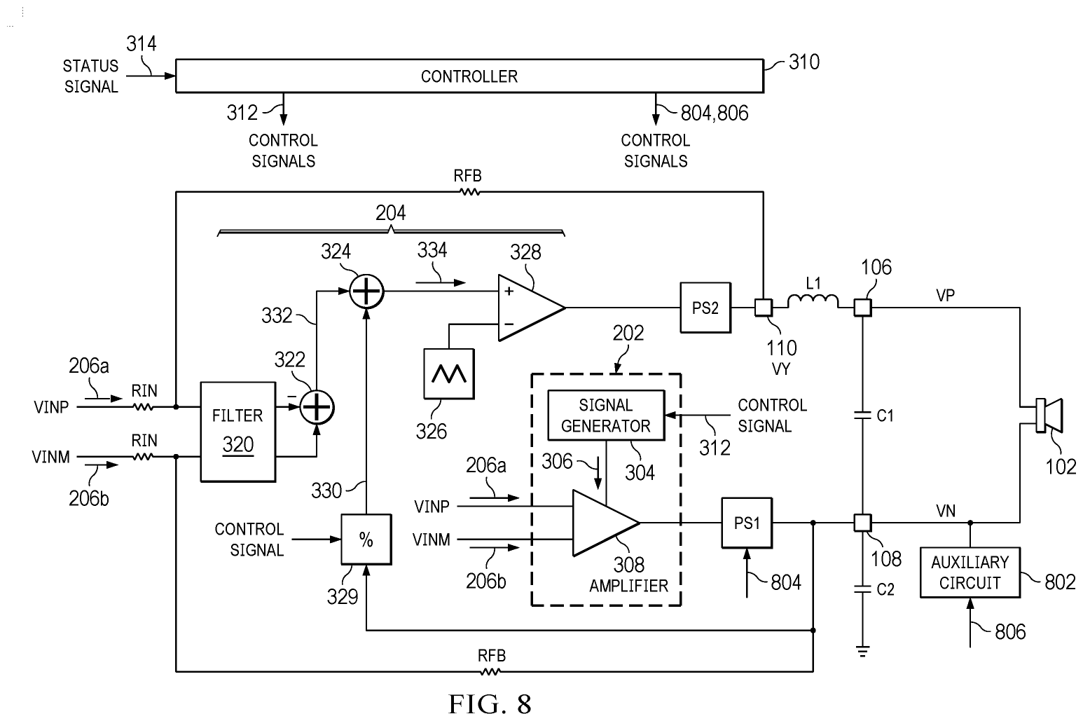

FIG. 7 illustrates a timing diagram, which illustrates an operation of the assist transistors AS1-AS4 of FIGS. 2A-2G and an operation of the power supply circuit 414 of FIGS. 4-6. For example, comparing the timing diagrams of FIGS. 2B and 6 with the timing diagram of FIG. 7, the assist transistors are on during time period t4 to t5, during which the GVDD_f provides power for operating the assist transistors AS1-AS4. The weak GVDD regulator 504 subsequently initiates at time t9, and the strong GVDD regulator 508 initiates at time t11.

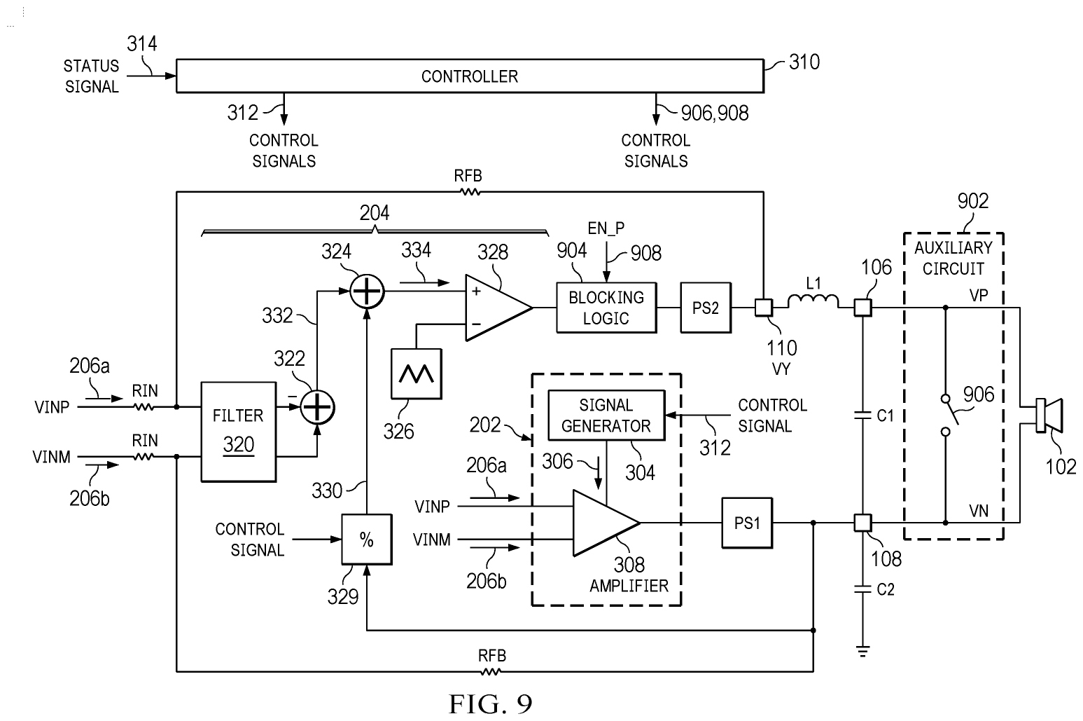

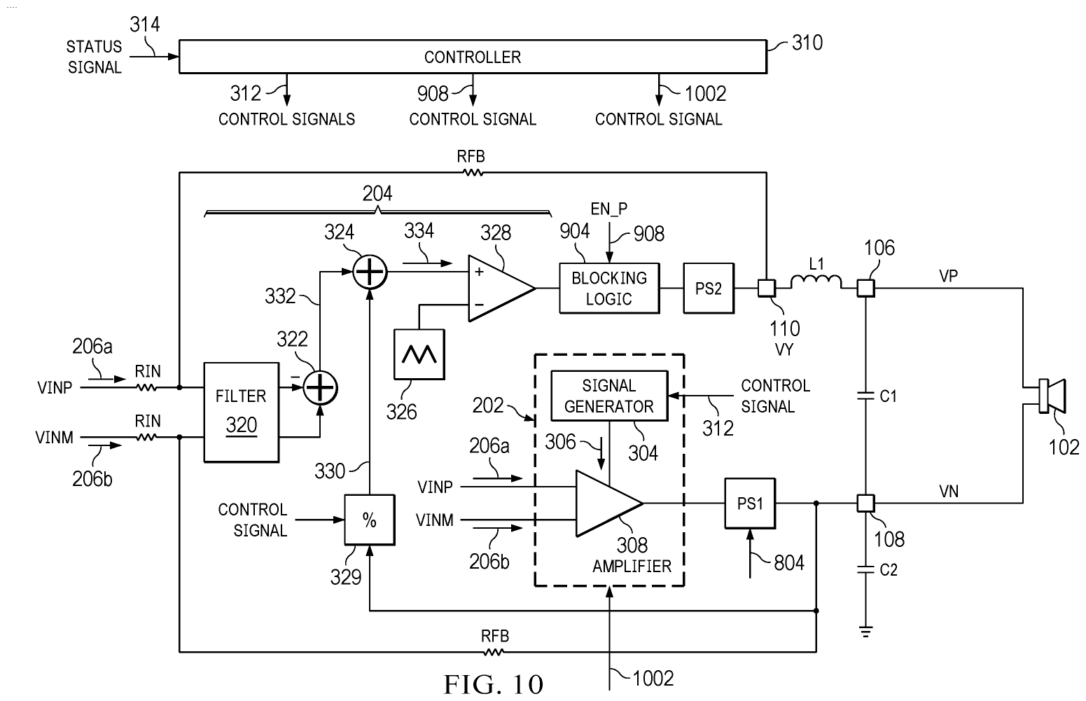

FIG. 8 illustrates another example implementation of the power supply control circuit 420 and the power supply circuit 414 of the system 400 of FIG. 4, and FIG. 9 illustrates a timing diagram depicting an operation of the power supply control circuit 420 and the power supply circuit 414 of FIG. 8.

For example, in FIGS. 5 and 6, the generation of the GVDD_En_delayed was a two-step process: (i) initially the power control signal GVDD_En was generated at time t10 by comparing the feedback of GVDD with Vref1, and (ii) subsequently the GVDD_En was delayed using the delay 428, to generate the GVDD_En_delayed at time t11. In contrast, in FIGS. 8 and 9, the undervoltage lockout circuit 424 directly generates the power control signal GVDD_En_delayed at time t11, e.g., by comparing the feedback of GVDD with another reference voltage Vref2. Thus, the GVDD_En_delayed of FIGS. 8 and 9 is generated at time t11, with the delay of FIGS. 5 and 6 already incorporated within the GVDD_En_delayed.

In an example, Vref2 of FIG. 8 is higher than Vref1 of FIG. 5. For example, for the example timing diagrams of FIGS. 6 and 9, Vref1 is 2.5 V, whereas Vref2 is 4.6 V in the example of FIGS. 8 and 9.

In an example, the above description of a relatively small jump in GVDD with respect to FIGS. 5 and 6 also applies to FIGS. 8 and 9. For example, the jump of GVDD in FIG. 9 at around time t11 is merely 0.5 V (as an example) or other jump criteria described above, and hence, the speaker 102 may not generate an audible pop noise.

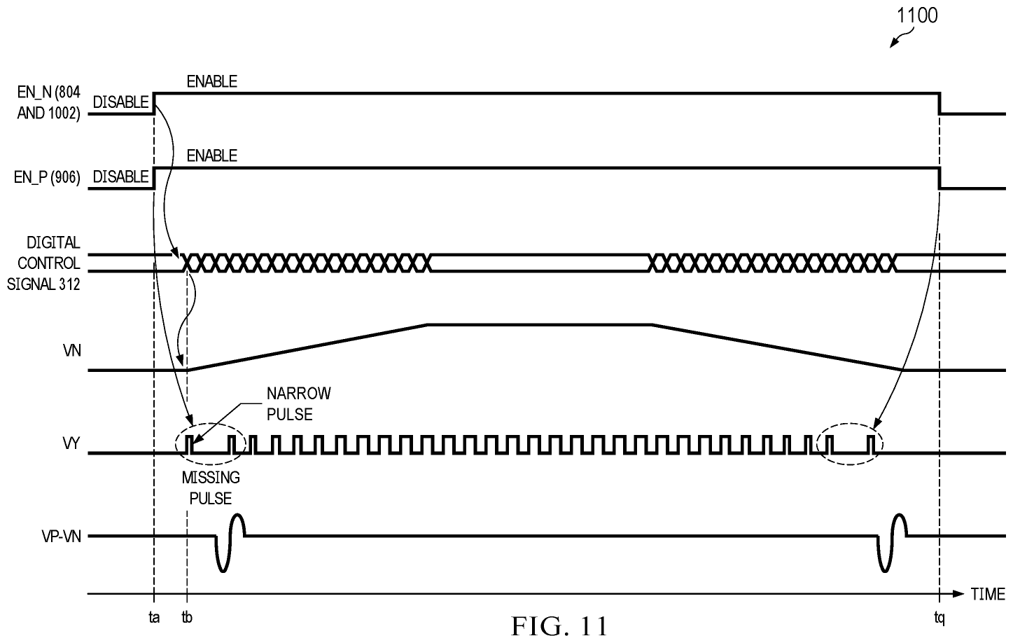

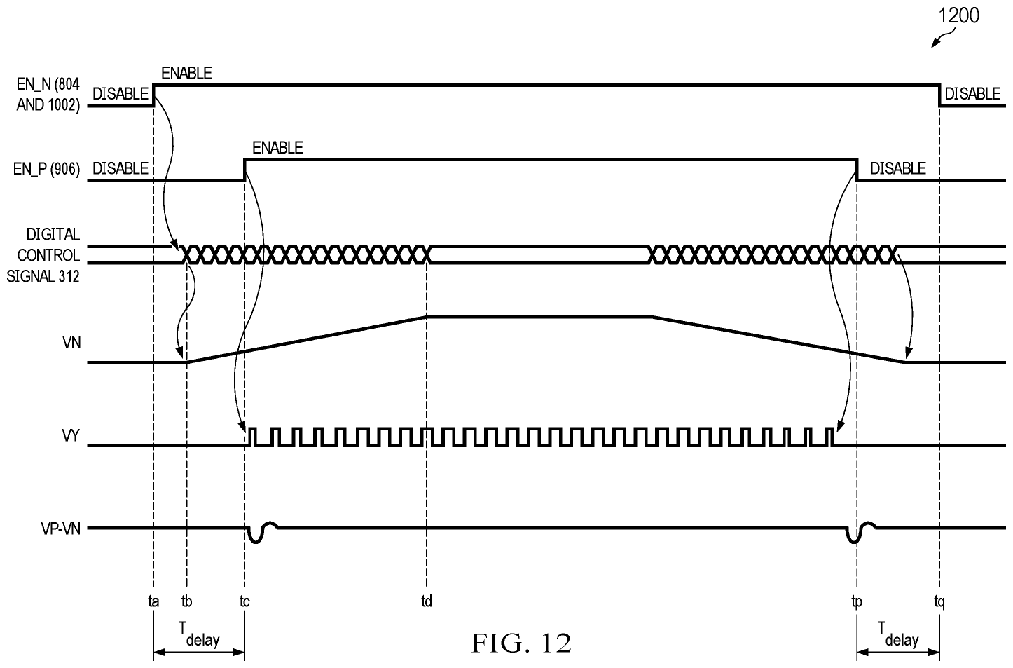

FIG. 10 illustrates yet an example implementation of the power supply circuit 414 of the system 400 of FIG. 4, and FIG. 11 illustrates a timing diagram depicting an operation of the power supply circuit 414 of FIG. 10. In the example of FIG. 10, the weak and strong voltage regulators are replaced by a single GVDD voltage regulator 524. The resultant GVDD plot in illustrated in FIG. 11. In an example, the GVDD regulator 524 ramps up the GDVV at a relatively slow slew rate equal to or lower than, for example, 1 V/20 microseconds, 1 V/5 microseconds, 1 V/1 microseconds, etc. Accordingly, the change in GVDD over time (e.g., dV/dT) is not high enough to cause a pop sound in the speaker 102.

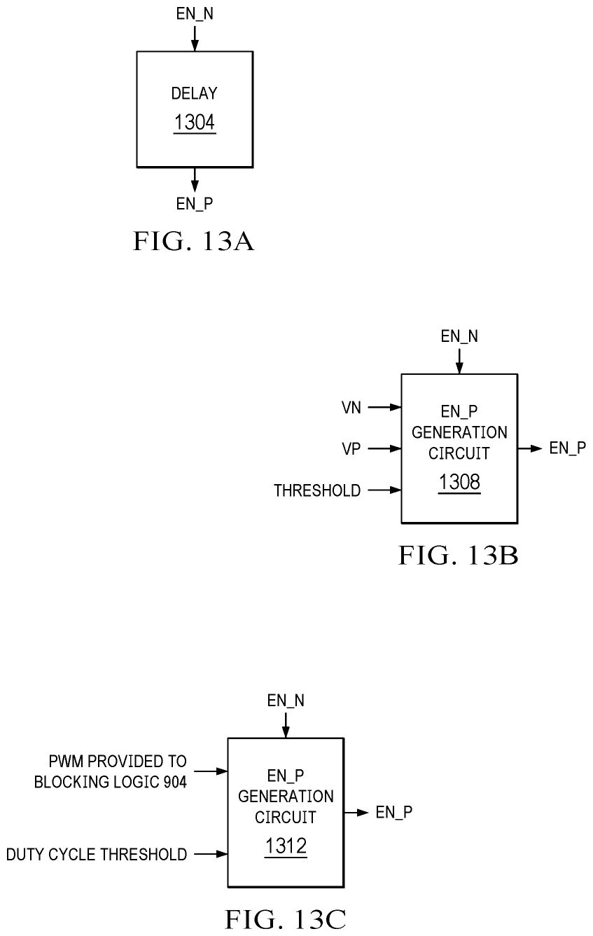

FIG. 12 is an example flowchart representative of a method 1200 of operating a speaker, such as speaker 102. Method 1200 can be performed by, for example, control circuit 203 in conjunction with the first power stage PS1 and the second power stage PS2 of FIGS. 2A-11. For example, the method 1200 is directed towards operations of the assist transistors AS1-AS4 described above.

At block 1204 of method 1200, receive a first voltage that ramps up at respective power terminals of a first power stage circuit and a second power stage circuit. In an example, the first power stage circuit has a first output and the second power stage circuit has a second output. For example, the first power stage circuit is PS1 of FIGS. 2A-2G having an output terminal 108, and the second power stage circuit is PS2 of FIGS. 2A-2G having an output terminal 110 (or the terminal 106, which may also be considered to be an output terminal of the power stage PS2). The first voltage is PVDD at the power terminals 116a and/or 116b, which ramps up at start-up or during a reset process.

The method 1200 proceeds from 1204 to 1208. At 1208, a determination is made as to whether the first voltage is below a threshold voltage, e.g., see operations of the undervoltage lockout circuit 308 of FIG. 3.

The method 1200 proceeds from 1208 to 1212. At 1212, responsive to the first voltage being below the threshold, the first and second outputs are set to a second voltage. For example, responsive to the first voltage being below the threshold (e.g., during time period t4 to t5 of FIG. 2B), the control signal generation circuit 207 of FIG. 3 enables the assist transistor control signal CSS, and the assist transistors AS1-AS4 are enabled or turned on. Accordingly, in the example of FIG. 2C, the output terminals 108 and 110 are grounded through the assist transistors AS2, AS4, respectively. In another example and as illustrated in FIG. 2D, the output terminal 108 and the speaker terminal 106 are grounded through the assist transistors AS2, AS4, respectively. In yet another example and as illustrated in FIG. 2E, the output terminal 108 and the speaker terminal 110 are shorted through the assist transistor AS2. In a further example and as illustrated in FIG. 2F, the output terminal 108 and the speaker terminal 110 are shorted and coupled to a common voltage VS. In an example, setting the first and second outputs to the second voltage eliminates or reduces possibilities of a pop noise from the speaker 102, e.g., due to substantially zero offset voltage difference between voltages VN and VP.

In an example, setting the first and second outputs to the second voltage implies that the first and second outputs are “substantially” equal to the second voltage. The voltage difference between the first and second outputs may be limited at various percentages of the of the voltages of the first and second outputs, such as 10%, 5%, 3%, or 2%, 1%, 0.5%, 0.1%, 0.01%, etc. of any.

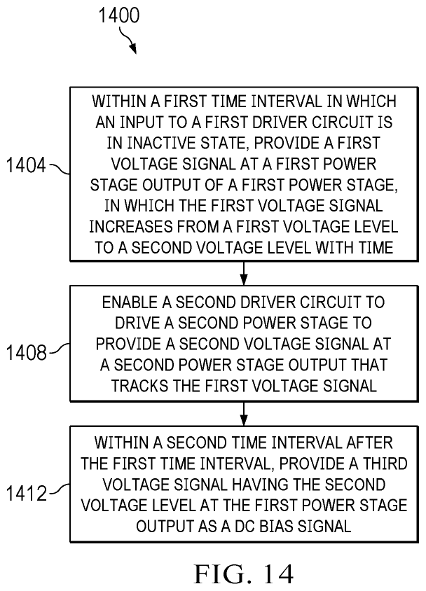

FIG. 13 is another example flowchart representative of a method 1300 of operating a speaker, such as speaker 102. Method 1300 can be performed by, for example, control circuit 203, power supply circuit 414, power supply control circuit 420, and in conjunction with the first power stage PS1 and the second power stage PS2 of FIGS. 2A-11. For example, the method 1300 is directed towards generation of regulated voltage GVDD at the power supply terminal 407 of the system 400 described above.

At block 1304, receives a first voltage that ramps up at a power supply circuit. In an example, the first power stage circuit is PS2 of FIGS. 2A-11. The first voltage is PVDD at the power terminals 116a and/or 116b, which ramps up at start-up or during a reset process. The first voltage is also received at a power terminal of a power stage circuit coupled to a speaker, such as first power stage PS1 and second power stage PS2.

The method 1300 proceeds from 1304 to 1308. At 1308, responsive to the first voltage reaching a first threshold voltage, a first voltage regulator to provide a second voltage at a driver power terminal of a driver circuit of the power stage circuit is enabled. For example, the first voltage regulator is the weak GVDD regulator 504, which is enabled based on the weak_en control signal 510 at time t9 described above. The second voltage is the GVDD voltage at the driver power terminal of the driver D3 of the power stage PS2.

The method 1300 then proceeds from 1308 to 1312. At 1312, after enabling of the first voltage regulator, a second voltage regulator (such as the strong voltage regulator 508) is enabled, to increase the second voltage (e.g., GVDD) by no more than a particular percentage of the second voltage or at no more than a particular slew rate, in which the percentage and the slew rate are based on a pop noise level limit at the speaker 102. For example, the strong voltage regulator 508 is enabled, such that the jump in GVDD is less than a threshold percentage or a threshold slew rate, which are tied to the pop noise level limit at the speaker, as described above.

### Further Examples

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (C) package) and may be adapted to be coupled to at least some of the passive elements and/or the sources to form the described structure either at a time of manufacture or after a time of manufacture, such as by an end user and/or a third party.

While the use of particular transistors is described herein, other transistors (or equivalent devices) may be used instead. For example, a p-channel field effect transistor (PFET) may be used in place of an n-channel field effect transistor (NFET) with little or no changes to the circuit. Furthermore, other types of transistors may be used (such as bipolar junction transistors (BJTs)). Furthermore, the devices may be implemented in/over a silicon substrate (Si), a silicon carbide substrate (SiC), a gallium nitride substrate (GaN) or a gallium arsenide substrate (GaAs).

References herein to a field effect transistor (FET) being “ON” means that the conduction channel of the FET is present and drain current may flow through the FET. References herein to a FET being “OFF” means that the conduction channel is not present and drain current does not flow through the FET. A FET that is OFF, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/− percent of that parameter.

Modifications are possible in the described embodiments and examples, and other embodiments and examples are possible, within the scope of the claims, such as the examples herein below.

Example 1. An apparatus comprising: a first power stage circuit having a first output and a first power terminal; a second power stage circuit having a second output and a second power terminal; and a control circuit having a control input, a first control output, and a second control output, the control input coupled to the power terminal, the first control output coupled to the first output, and the second control output coupled to the second output, the control circuit configured to, responsive to a first voltage at the first and second power terminals being below a threshold voltage, set the first output to a second voltage and the second output to a third voltage.

Example 2. The apparatus of example 1, wherein the control circuit includes: a first transistor coupled between the first control output and a first voltage terminal; and a second transistor coupled between the second control output and a second voltage terminal, wherein the control circuit is configured to enable the first and second transistors responsive to the first voltage being below the threshold voltage.

Example 3. The apparatus of example 2, wherein the first and second voltage terminals are ground terminals.

Example 4. The apparatus of any one of examples 2-3, wherein the first voltage terminal is coupled to first voltage source configured to a first direct current (DC) voltage, and the second voltage terminal is coupled to a second voltage source configured to provide a second DC voltage.

Example 5. The apparatus of example 4, wherein the first and second DC voltages are substantially same.

Example 6. The apparatus of example 4, wherein the first and second DC voltages are different DC voltages.

Example 7. The apparatus of any one of examples 2-6, wherein the first voltage terminal and the second voltage terminal are coupled to a voltage source, and the first and second voltages are a same voltage.

Example 8. The apparatus of any one of examples 1-7, wherein the control circuit includes a transistor coupled between the first and second control outputs, and the control circuit is configured to enable the transistor responsive to the first voltage being below the threshold voltage.

Example 9. The apparatus of any one of examples 1-8, wherein: the control circuit has a third control output, and a fourth control output; and the first power stage circuit has a first power stage control input, the second power stage circuit has a second power stage control input, the first power stage control input is coupled to the third control output, and the second power stage control input is coupled to the fourth control output; wherein the control circuit is configured to set the first and second power stage control inputs to a disabled state responsive to the first voltage at the first and second power terminals being below the threshold; wherein the first power stage circuit is configured to disconnect the first output from the first power terminal responsive to the first power stage control input being in the disabled state; and wherein the second power stage circuit is configured to disconnect the second output from the second power terminal responsive to the second power stage control input being in the disabled state.

Example 10. The apparatus of example 9, wherein the control circuit includes: a first transistor coupled between the third control output and a voltage terminal; and a second transistor coupled between the fourth control output and the voltage terminal, wherein the control circuit is configured to enable the first and second transistors responsive to the first voltage being below the threshold.

Example 11. The apparatus of example 10, wherein the voltage terminal is aground terminal.

Example 12. The apparatus of any one of examples 9-10, wherein: the first power stage has a third power stage control input and includes: a first transistor coupled between the first power terminal and the first output, the first transistor having a first control terminal coupled to the first power stage control input; and a second transistor coupled between the first output and a ground terminal, the second transistor having a second control terminal coupled to the third power stage control input; and the second power stage has a fourth power stage control input and includes: a third transistor coupled between the second power terminal and the second output, the third transistor having a third control terminal coupled to the second power stage control input; and a fourth transistor coupled between the second output and the ground terminal, the fourth transistor having a fourth control terminal coupled to the fourth power stage control input.

Example 13. The apparatus of any one of examples 1-12, wherein the control circuit has a power supply control output and is configured to provide a power supply control signal at the power supply control output responsive to the first voltage at the first and second power terminals exceeding a second threshold voltage; and wherein the apparatus further comprises: a first driver circuit having a first driver output, the first driver output coupled to a first power stage control input; a second driver circuit having a second driver output and a driver power terminal, the second driver output coupled to a second power stage control input; a third driver circuit having a third driver output, the third driver output coupled to a third power stage control input; a fourth driver circuit having a fourth driver output, the fourth driver output coupled to a fourth power stage control input; and a power supply circuit having a power input, a power supply control input and a power output, the power input coupled to the first and second power terminals, the power supply control input coupled to the power supply control output, the power output coupled to the driver power terminal via a third power terminal, the power supply circuit configured to provide a fourth voltage at the driver power terminal, and increase the fourth voltage responsive to the power supply control signal.

Example 14. The apparatus of example 13, wherein the power supply circuit is configured to, responsive to the power supply control signal, increase the fourth voltage by no more than a particular percentage of the fourth voltage or at no more than a particular slew rate, in which the percentage and the slew rate are based on a speaker pop noise limit.

Example 15. The apparatus of any one of examples 13-14, wherein the power supply control signal is a first power supply control signal, the power supply control input is a first power supply control input, the control circuit has a second power supply control output, the power supply circuit has a second power supply control input coupled to the second power supply control output, and the power supply circuit includes: a first voltage regulator having a first regulator input, a first regulator enable input, and a first regulator output, the first regulator input coupled to the power input, the first regulator enable input coupled to the first power supply control input, the first regulator output coupled to the power output, and the first voltage regulator is enabled responsive to the first power supply control signal; and a second voltage regulator having a second regulator input, a second regulator enable input, and a second regulator output, the second regulator input coupled to the power input, the second regulator enable input coupled to the second power supply control input, and the second regulator output coupled to the power output, the second voltage regulator configured to supply a smaller current at the power output than the first voltage regulator and is enabled responsive to a second power supply control signal at the second regulator enable input; wherein the control circuit is configured to provide the second power supply control signal to enable the second voltage regulator, followed by providing the first power supply control signal to enable the first voltage regulator.

Example 16. The apparatus of example 15, wherein the control input is a first control input, the control circuit has a second control input coupled to the third power terminal, and the control circuit is configured to provide the first power supply control signal responsive to the second voltage exceeding a third threshold voltage.

Example 17. The apparatus of example 16, wherein the control circuit is configured to provide a third power supply control signal responsive to the second voltage exceeding the third threshold voltage, and the control circuit includes a delay circuit configured to provide the third power supply control signal by adding a particular delay to the third power supply control signal.

Example 18. The apparatus of any one of examples 13-17, further comprising a bootstrap circuit coupled between the second power terminal and the driver power terminal.

Example 19. The apparatus of any one of examples 1-18, wherein the first and second power stages and the control circuit are part of an integrated circuit.

Example 20. An apparatus comprising: a first power stage circuit having a first output and a first power terminal; a second power stage circuit having a second output and a second power terminal; a capacitor coupled between the first output and a ground terminal; a speaker having a first speaker terminal and a second speaker terminal, the first speaker terminal coupled to the first output; an inductor coupled between the second output and the second speaker terminal; and a control circuit having a control input, a first control output, and a second control output, the control input coupled to the first and second power terminals, the first control output coupled to the first output, and the second control output coupled to the second output or the second speaker terminal, the controller configured to, responsive to a first voltage at the first and second power terminals being below a threshold voltage, set the first output to a second voltage and the second output to a third voltage.

Example 21. The apparatus of example 20, wherein the control circuit includes: a first transistor coupled between the first control output and a first voltage terminal; and a second transistor coupled between the second control output and a second voltage terminal, wherein the control circuit is configured to enable the first and second transistors responsive to the first voltage being below the threshold voltage.

Example 22. The apparatus of example 21, wherein each of the first and second voltage terminals is a ground terminal.

Example 23. A method comprising: receiving a first voltage that ramps up at respective power terminals of a first power stage circuit and a second power stage circuit, in which the first power stage circuit has a first output and the second power stage circuit has a second output; determining whether the first voltage is below a threshold; and responsive to the first voltage being below the threshold, setting the first and second outputs to a second voltage.

Example 24. The method of example 23, wherein the second voltage is a voltage of a ground terminal.

Example 25. A method comprising: receiving a first voltage that ramps up at a first power terminal of a power stage circuit coupled to a speaker and at a second power terminal of a power supply circuit; responsive to the first voltage reaching a first threshold voltage, enabling a first voltage regulator of the power supply circuit to provide a second voltage at a driver power terminal of a driver circuit of the power stage circuit; and after enabling of the first voltage regulator, enabling a second voltage regulator of the power supply circuit to increase the second voltage by no more than a particular percentage of the second voltage or at no more than a particular slew rate, in which the percentage or slew rate is based on a pop noise level limit at the speaker.

Example 26. The method of example 25, wherein enabling the second voltage regulator includes enabling the second voltage regulator responsive to the second voltage exceeding a threshold voltage.

Example 27. The method of example 27, wherein enabling the second voltage regulator includes enabling the second voltage regulator after a delay time has elapsed from when the second voltage exceeds the threshold voltage.

What is claimed is:

1. An apparatus comprising:
a first power stage having a first power stage input and a first power stage output;
a second power stage having a second power stage input and a second power stage output;
a first driver circuit having a first driver input and a first driver output, the first driver output coupled to the first power stage input;
a control circuit configured to, responsive to the first driver input being in an inactive state, set the first power stage output; and
a second driver circuit having a second driver input and a second driver output, the second driver output coupled to the second power stage input, and the second driver input coupled to the first power stage output, and the second driver circuit configured to set the second power stage output to track the first power stage output.

2. The apparatus of claim 1, wherein the control circuit has at least one of a startup input or a shutdown input and configured to determine that the first driver input is in the inactive state responsive to a startup signal at the startup input or a shutdown signal at the shutdown input.

3. The apparatus of claim 1, wherein the control circuit is configured to set the first power stage output to one of a first voltage or a second voltage, in which the first voltage increases from a first voltage level to a second voltage level with time, and the second voltage decreases from the second voltage level to the first voltage level with time; and
the second driver circuit is configured to control the second power stage output to provide a third voltage to track the first voltage signal, and to provide a fourth voltage to track the second voltage.

4. The apparatus of claim 3, wherein each of the first and second voltages includes a respective linear voltage ramp.

5. The apparatus of claim 1, wherein the control circuit includes an auxiliary power stage having an auxiliary output coupled to the first power stage output, and the control circuit is configured to:
responsive to the first driver input being the inactive state, control the auxiliary power stage to set the first power stage output via the auxiliary output; and
responsive to the first driver input being in an active state, disable the auxiliary power stage.

6. The apparatus of claim 1, wherein the first driver circuit includes a first stage and a second stage, the first stage has the first driver input and a first stage output, the second stage has a second stage input coupled to the first stage output and the first driver output, the control circuit configured to set the first power stage output by providing a signal at the second stage input.

7. The apparatus of claim 3, wherein the control circuit is configured to:
at a first time, start setting the first power stage output at the first voltage and disable the second driver circuit from setting the second power stage output;
at a second time after the first time, while providing the first voltage signal, enable the second driver circuit to set the second power stage output;
between a third time and a fourth time, provide the second voltage; and
at a fifth time before the fourth time, disable the second driver circuit from setting the second power stage output.

8. The apparatus of claim 7, wherein the control circuit is configured to determine the second time based on a pre-configured time difference from the first time and determine the fifth time based on the pre-configured time difference from the fourth time.

9. The apparatus of claim 7, wherein the controller is configured to determine the second time based on the first voltage signal exceeding a first threshold and determine the fifth time based on the second voltage falling below a second threshold.

10. The apparatus of claim 7, wherein the control circuit includes an auxiliary circuit and configured to control the auxiliary circuit to, while disabling the second driver circuit, provide a signal at the second power stage output to track the first power stage output.

11. The apparatus of claim 10, wherein the auxiliary circuit includes at least one of: a switch coupled between the first and second power stage outputs, or an amplifier having an amplifier output coupled to the first power stage output.

12. The apparatus of claim 1, wherein the control circuit is configured to set a direct current (DC) voltage at the first power stage output when the first driver input is in active state.

13. The apparatus of claim 12, wherein the first power stage has a first power input coupled to a power terminal, the second power stage has a second power input coupled to the power terminal, and the control circuit is configured to set the DC voltage based on a second voltage at the power terminal.

14. The apparatus of claim 12, wherein the DC voltage is a first DC voltage, the first driver circuit includes a first stage and a second stage, the first stage has the first driver input and a first stage output, the second stage has a second stage input coupled to the first stage output and the first driver output, the control circuit configured to set the first DC voltage by setting a second DC voltage at the second stage input.

15. The apparatus of claim 14, wherein the second stage input includes first differential inputs, and the controller includes:
a differential pair having second differential inputs and differential outputs, the differential outputs coupled to the first differential inputs; and
a voltage generator having a generator output coupled to a first input of the second differential inputs; and
wherein a second input of the second differential inputs is coupled to the first power stage output.

16. The apparatus of claim 15, wherein the voltage generator has a control input, and the apparatus further comprises a calibration circuit having a reference input, a calibration input, and a calibration output, the calibration input coupled to the first power stage output, and the calibration output coupled to the control input.

17. The apparatus of claim 1, wherein the first driver circuit is configured to provide a first driver signal at the first driver output, the first driver signal being linearly related to a signal at the first driver input; and
the second driver circuit is configured to provide a second driver signal at the second driver output, the second driver signal being a pulse width modulated (PWM) signal.

18. The apparatus of claim 17, further comprising:
a first capacitor coupled between the first power stage output and a ground terminal;
an inductor coupled between the second power stage output and a speaker output terminal; and
a second capacitor coupled between the first power stage output and the speaker output terminal.

19. The apparatus of claim 18, further comprising a speaker coupled between the first power stage output and the speaker output terminal.

20. An apparatus comprising:
a first power stage having a first power input coupled to a power terminal, a first power stage input, and a first power stage output;
a second power stage having a second power input coupled to the power terminal, a second power stage input, and a second power stage output;
a first driver circuit having a first driver input and a first driver output, the first driver output coupled to the first power stage input;
a second driver circuit having a second driver input and a second driver output, the second driver output coupled to the second power stage input, and the second driver input coupled to the first power stage output, and the second driver circuit configured to set the second power stage output to track the first power stage output; and
a control circuit configured to set a DC voltage of the first power stage output based on a second voltage at the power terminal.

21. The apparatus of claim 20, wherein the control circuit is configured to, responsive to the first driver input being in an inactive state, set the first power stage output to one of a first voltage or a second voltage, in which the first voltage increases from a first voltage level to a second voltage level with time, and the second voltage decreases from the second voltage level to the first voltage level with time.

22. An apparatus comprising:
a first power stage having a power terminal, a first power stage input, and a first power stage output;
a second power stage having the power terminal, a second power stage input, and a second power stage output;
a first driver circuit having a first driver input and a first driver output, the first driver output coupled to the first power stage input;
a second driver circuit having a second driver input and a second driver output, the second driver output coupled to the second power stage input, and the second driver input coupled to the first power stage output, and the second driver circuit configured to set a state of the second power stage output to track the state of the first power stage output; and
a control circuit coupled to the first power stage output and configured to:
at a first time, start setting the first power stage output at a first voltage and disable the second driver circuit from setting the second power stage output, in which the first voltage increases from a first voltage level to a second voltage level with time; and
at a second time after the first time, while providing the first voltage, enable the second driver circuit to set the second power stage output.

23. The apparatus of claim 22, wherein the control circuit is configured to:
between a third time and a fourth time, provide a second voltage, in which the second voltage decreases from the second voltage level to the first voltage level with time; and
at a fifth time before the fourth time, disable the second driver circuit from setting the second power stage output.

24. The apparatus of claim 23, wherein the first voltage increases from a first voltage level to a second voltage level with time, and the second voltage decreases from the second voltage level to the first voltage level with time.

25. A method comprising:
within a first time interval in which an input to a first driver circuit is in inactive state, providing a first voltage signal at a first power stage output of a first power stage, in which the first voltage signal increases from a first voltage level to a second voltage level with time;
enabling a second driver circuit to drive a second power stage to provide a second voltage signal at a second power stage output that tracks the first voltage signal; and
within a second time interval after the first time interval, providing a third voltage signal having the second voltage level at the first power stage output as a DC bias signal.

26. The method of claim 25, wherein the second voltage level is based on a power supply voltage of the first and second power stages.

27. The method of claim 25, wherein the input of the first driver circuit is in an active state within the second time interval.

28. The method of claim 25, further comprising, within a third time interval in which the input is in the inactive state, providing a fourth voltage signal at the first power stage output, in which the fourth voltage signal decreases from the second voltage level to the first voltage level with time.

29. The method of claim 28, wherein each of the first and fourth voltage signals includes a respective linear ramp signal.

30. The method of claim 25, wherein within the first-time interval in which the input the first driver circuit is in the inactive state, providing the first voltage signal includes:
within a first sub-interval of the first time interval, disabling the second driver circuit from setting a state of the second power stage output; and
within a second sub-interval of the first time interval, enabling the second driver circuit to set the state of the second power stage output, in which the voltage level of the first voltage signal increases from the first sub-interval to the second sub-interval.
